(19) United States
(12) Patent Application Publication
(10) Pub. No.: US 2024/0395989 A1
(43) Pub. Date: Nov. 28, 2024

(54) DISPLAY DEVICE

(71) Applicant: SAMSUNG DISPLAY CO., LTD., Yongin-Si (KR)

(72) Inventors: Ji Wook MOON, Yongin-si (KR); Jong Moo HUH, Yongin-si (KR); Ju Yon LEE, Yongin-si (KR); Min Woo KIM, Yongin-si (KR); Dong Jun LEE, Yongin-si (KR)

(21) Appl. No.: 18/591,204

(22) Filed: Feb. 29, 2024

(30) Foreign Application Priority Data
May 26, 2023 (KR) 10-2023-0068713

(51) Int. Cl. H01L 33/60; G09G 3/20; H01L 25/16; H01L 33/62

(52) U.S. Cl. CPC H01L 33/60; G09G 3/20; H01L 25/167; H01L 33/62; G09G 2300/0819; G09G 2300/0842; G09G 2300/0852

(57) ABSTRACT

A display device includes a substrate. A pixel electrode is disposed on the substrate. The pixel electrode has one or more grooves defined therein. Light emitting elements are respectively disposed in the one or more grooves.

### CROSS-REFERENCE TO RELATED APPLICATION

This application claims priority under 35 U.S.C. § 119 to Korean Patent Application No. 10-2023-0068713, filed on May 26, 2023 in the Korean Intellectual Property Office, the disclosure of which is incorporated by reference in its entirety herein.

### 1. TECHNICAL FIELD

The present disclosure relates to a display device.

### 2. DISCUSSION OF RELATED ART

Display devices have become increasingly important along with the development of the information society. Various types of display devices have been developed, such as organic light emitting displays (OLED) and liquid crystal displays (LCD).

A device for displaying an image of a display device includes a display panel, such as an organic light emitting display panel or a liquid crystal display panel. Among them, the light emitting display panel may include a light emitting element. For example, light emitting diodes (LED) include organic light emitting diodes (OLED) that utilize organic materials as light emitting materials, inorganic light emitting diodes that utilize inorganic materials as light emitting materials or the like.

### SUMMARY

Aspects and features of embodiments of the present disclosure provide a display device and a manufacturing method thereof that may prevent misalignment and mixing of light emitting elements.

However, aspects of the present disclosure are not restricted to those set forth herein. The above and other aspects of embodiments of the present disclosure will become more apparent to one of ordinary skill in the art to which the present disclosure pertains by referencing the detailed description of the present disclosure given below.

According to an embodiment, a display device includes a substrate. A pixel electrode is disposed on the substrate. The pixel electrode has one or more grooves defined therein. Light emitting elements are respectively disposed in the one or more grooves.

In an embodiment, the display device further includes a planarization layer disposed between the light emitting elements and a common electrode disposed on the planarization layer and the light emitting elements.

In an embodiment, a depth of the one or more grooves is in a range of about 10% to about 90% of a thickness of the pixel electrode.

In an embodiment, each of the light emitting elements disposed in the one or more grooves includes an active layer. The depth of each of the one or more grooves is greater than a height of the active layer.

In an embodiment, each of the light emitting elements disposed in the one or more grooves includes an active layer disposed within the one or more grooves.

In an embodiment, each of the one or more grooves has a bottom surface and an inclined surface extending from the bottom surface. An inclined angle formed between the inclined surface of the one or more grooves and the bottom surface of the one or more grooves is in a range of about 90 degrees to about 160 degrees.

In an embodiment, a reflective layer is disposed on the inclined surface of the one or more grooves and the bottom surface of the one or more grooves. The reflective layer has a higher reflectivity than a reflectivity of the pixel electrode.

In an embodiment, the reflective layer has a reflectivity greater than or equal to about 80%.

In an embodiment, an area of each of the bottom surface of each of the one or more grooves is in a range of about 110% to about 200% of an area of the light emitting elements disposed within each of the one or more grooves.

In an embodiment, the display device further includes a wavelength conversion part disposed on the common electrode. The wavelength conversion part includes a partition wall separating light emitting areas from non-emitting areas. A wavelength conversion layer is disposed between the partition walls and overlaps the light emitting areas. A light blocking member is disposed on the partition wall. Color filters are disposed on the wavelength conversion layer.

According to an embodiment of the present disclosure, a display device includes a substrate. Pixel electrodes are disposed on the substrate. Each of the pixel electrodes has one or more grooves defined therein. The one or more grooves are spaced apart from each other. Light emitting elements are respectively disposed within the one or more grooves. The light emitting elements are disposed on different pixel electrodes of the pixel electrodes emit light having different wavelengths from each other. A center of the one or more grooves is disposed on a respective central axis of the pixel electrodes.

In an embodiment, the light emitting elements include a first light emitting element having a center wavelength band in a range of 420 nm to 480 nm. A second light emitting element has a center wavelength band in a range of 500 nm to 580 nm. A third light emitting element has a center wavelength band in a range of 600 nm to 680 nm.

In an embodiment, the display device further includes a planarization layer disposed between the light emitting elements and a common electrode disposed on the planarization layer and the light emitting elements.

In an embodiment, a depth of each of the one or more grooves is in a range of about 10% to about 90% of a thickness of each of the pixel electrodes.

In an embodiment, each of the light emitting elements disposed in the one or more grooves includes an active layer. A depth of each of the one or more grooves is greater than a height of the active layer.

In an embodiment, each of the one or more grooves has a bottom surface and an inclined surface extending from the bottom surface. An inclined angle formed between the inclined surface of each of the one or more grooves and the bottom surface of each of the one or more grooves is in a range of about 90 degrees to about 160 degrees.

In an embodiment, a reflective layer is disposed on the inclined surface of the one or more grooves and the bottom surface of the one or more grooves, the reflective layer has a higher reflectivity than a reflectivity of the pixel electrodes.

In an embodiment, the reflective layer has a reflectivity greater than or equal to about 80%.

In an embodiment, an area of the bottom surface of each of the one or more grooves is in a range of about 110% to about 200% of an area of each of the light emitting elements disposed within the one or more grooves.

In an embodiment, the display device further includes a wavelength conversion part disposed on the common electrode. The wavelength conversion part includes partition walls separating light emitting areas from non-emitting areas. A wavelength conversion layer is disposed between the partition walls and overlapping the light emitting areas. A light blocking member is disposed on the partition walls. Color filters are disposed on the wavelength conversion layer.

According to embodiments of the present disclosure, the display device may includes a groove formed in the pixel electrode, and alignment of the light emitting element with the formed groove may be facilitated. Accordingly, misalignment of the light emitting element may be prevented.

Furthermore, according to embodiments of the present disclosure, a display device may include a reflective layer formed in the groove of the pixel electrode to prevent light from the light emitting element from invading the adjacent light emitting area and causing color mixing.

However, the effects of embodiments of the present disclosure are not necessarily limited to the aforementioned effects, and various other effects are included in the present specification.

### BRIEF DESCRIPTION OF THE DRAWINGS

FIG. 1 is a plan view of a display device according to an embodiment.

FIG. 2 is a schematic layout view of a circuit of a display substrate of a display device according to an embodiment.

FIG. 3 is an equivalent circuit diagram of one pixel of a display device according to an embodiment.

FIG. 4 is an equivalent circuit diagram of one pixel of a display device according to an embodiment.

FIG. 5 is an equivalent circuit diagram of one pixel of a display device according to an embodiment.

FIG. 6 is a cross-sectional view schematically illustrating a portion of a display area of the display device of FIG. 1.

FIG. 7 is a perspective view illustrating a pixel electrode according to an embodiment.

FIG. 8 is a perspective view illustrating a pixel electrode and a light emitting element of a display device according to an embodiment.

FIG. 9 is a plan view of FIG. 8.

FIG. 10 is an enlarged view of area A of FIG. 6.

FIG. 11 is a plan view schematically illustrating a plurality of light emitting areas and a plurality of color filters.

FIG. 12 is a cross-sectional view schematically illustrating a display device according to an embodiment.

FIG. 13 is a schematic cross-sectional view of a display device according to an embodiment.

FIGS. 14 to 24 are diagrams to illustrate a manufacturing method of a display device according to an embodiments of the present disclosure.

FIGS. 25 to 31 are cross-sectional views illustrating a manufacturing process of a display device according to embodiments of the present disclosure.

FIG. 32 is a diagram schematically showing a virtual reality device including a display device according to an embodiment;

FIG. 33 is a diagram schematically showing a smart device including a display device according to an embodiment;

FIG. 34 is a diagram of an example schematically showing a vehicle including a display device according to an embodiment.

FIG. 35 is a diagram of an example schematically showing a transparent display device including a display device according to an embodiment.

### DETAILED DESCRIPTION OF EMBODIMENTS

The embodiments will now be described more fully hereinafter with reference to the accompanying drawings. Embodiments of the present disclosure may, however, be provided in different forms and the described embodiments should not be construed as limiting. The same reference numbers indicate the same components throughout the disclosure. In the accompanying figures, the thickness of layers and regions may be exaggerated for clarity.

Some of the parts which are not associated with the description may not be provided to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, no intervening elements may be present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relationship between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments of the present disclosure will be described in detail with reference to the accompanying drawings.

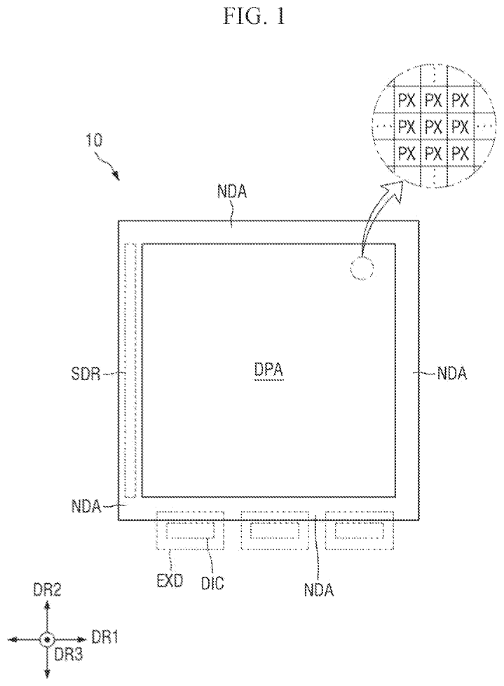

FIG. 1 is a plan view of a display device according to an embodiment.

Referring to FIG. 1, a display device 10 according to an embodiment may be applied to various consumer electronics, or internet of things devices, such as smartphones, cell phones, tablet PC, personal digital assistants (PDA), portable multimedia players (PMP), televisions, gaming devices, watch-type electronic devices, head-mounted displays, monitors of personal computers, laptop computers, car navigation, car instrument panels, digital cameras, camcorders, exterior billboards, billboards, medical devices, inspection devices, refrigerators, and washing machines, or the like. However, embodiments of the present disclosure are not necessarily limited thereto. A television is described herein as an example of the display device, and the television may have a high or ultra-high resolution, such as HD, UHD, 4K, 8K, etc.

In addition, the display device 10 according to some embodiments may be variously categorized based on how it is displayed. For example, the classification of the display device may include an organic light emitting display device (OLED), an inorganic light emitting display device (inorganic EL), a quantum dot light emitting display device (QED), a micro-LED display device (micro-LED), a nano-LED display device (nano-LED), a plasma display device (PDP), a field emission display device (FED), a cathode ray display device (CRT), a liquid crystal display device (LCD), an electrophoretic display device (EPD), or the like. In the following, the organic light emitting display device will be described as an example of a display device, and the organic light emitting display device applied in an embodiment will be abbreviated simply as a display device unless otherwise indicated. However, embodiments of the present disclosure are not necessarily limited to organic light emitting display device, and other display devices listed above or known in the art may be employed to the extent that they share technical ideas.

Furthermore, in the following drawings, a first direction DR1 refers to a horizontal direction of the display device 10, a second direction DR2 refers to a vertical direction of the display device 10, and a third direction DR3 refers to a thickness direction of the display device 10. In an embodiment, the first to third directions DR1, DR2, DR3 may be perpendicular to each other. However, embodiments of the present disclosure are not necessarily limited thereto. In this case, “left”, “right”, “up”, and “down” refer to directions when the display device 10 is viewed from a plane. For example, “right” refers to one side of the first direction DR1, “left” refers to the other side of the first direction DR1, “top” refers to one side of the second direction DR2, and “bottom” refers to the other side of the second direction DR2. Further, “upper” refers to a first side of the third direction DR3 and “lower” refers to a second side of the third direction DR3.

The display device 10 according to an embodiment may have a square shape in a plan view. Also, if the display device 10 is a television, it may have a rectangular shape with the relatively long sides disposed in the transverse direction. However, embodiments of the present disclosure are not necessarily limited thereto. For example, the relatively long sides may be disposed in the longitudinal direction, and the display device 10 may be rotatably mounted so that the relatively long sides are variably disposed in the horizontal or vertical direction. The display device 10 may also have a circular or oval shape or another polygonal shape in some embodiments.

The display device 10 may include a display area DPA and a non-display area NDA. The display area DPA may be an active area where the video is displayed. The display area DPA may have a square shape in a plan view similar to the overall shape of the display device 10. However, embodiments of the present disclosure are not necessarily limited thereto.

The display area DPA may include a plurality of pixels PX. The plurality of pixels PX may be arranged in a matrix orientation. The shape of each pixel PX may be rectangular or square in plan view. However, embodiments of the present disclosure are not necessarily limited thereto. For example, in an embodiment each pixel PX may also be rhombic in shape with each side inclined toward one side of the display device 10. The plurality of pixels PX may include multiple color pixels PX. For example, in an embodiment the plurality of pixels may include a first color pixel PX of red, a second color pixel PX of green, and a third color pixel PX of blue. However, embodiments of the present disclosure are not necessarily limited thereto and the colors of the pixels PX and the numbers of the different pixels PX may vary. Each color pixel PX may be alternately arranged in a stripe-type or a pentile-type.

In an embodiment, the non-display area NDA may be disposed on the periphery of the display area DPA (e.g., in the first and second directions DR1, DR2). The non-display area NDA may fully or partially enclose the display area DPA. In an embodiment, the display area DPA may be square in shape, and the non-display areas NDA may be arranged to be adjacent to the four sides of the display area DPA. The non-display area NDA may comprise a bezel of the display device 10.

A driving circuit or a driving element for driving the display area DPA may be disposed in the non-display area NDA. In an embodiment, the non-display area NDA disposed adjacent to the first side (lower side in FIG. 1) of the display device 10 may have a pad portion provided on the display substrate of the display device 10, and an external device EXD may be mounted on the pad electrode of the pad portion. Examples of the external device EXD include a connection film, a printed circuit board, a driving chip (DIC), a connector, a wiring connection film, or the like. However, embodiments of the present disclosure are not necessarily limited thereto. In the non-display area NDA disposed adjacent to the second side (left side in FIG. 1) of the display device 10, a scan driving unit SDR, or the like formed directly on the display substrate of the display device 10 may be disposed.

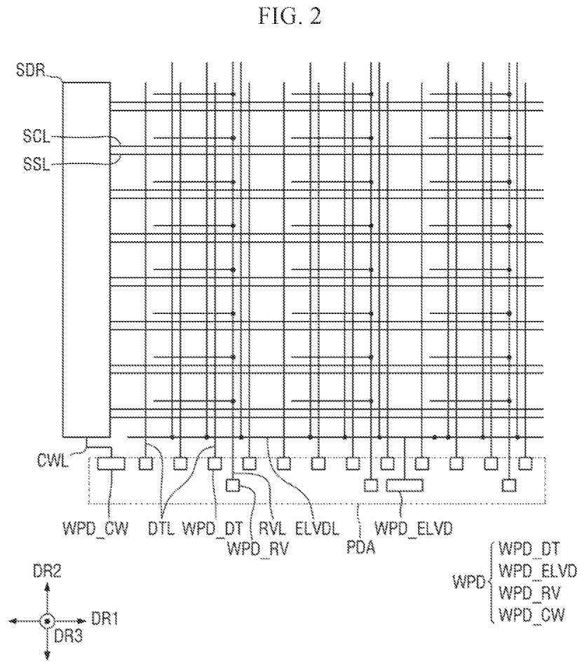

FIG. 2 is a schematic layout view of a circuit of a display substrate of a display device according to an embodiment.

Referring to FIG. 2, a plurality of lines is disposed on the first substrate. In an embodiment, the plurality of lines may include a scan line SCL, a sensing signal line SSL, a data line DTL, a reference voltage line RVL, a first power supply line ELVDL, or the like.

In an embodiment, the scan line SCL and the sensing signal line SSL may extend in the first direction DR1. The scan line SCL and the sensing signal line SSL may be connected to the scan driving unit SDR. The scan driving unit SDR may include a driving circuit. In an embodiment, the scan driving unit SDR may be disposed on one side of the non-display area NDA on the display substrate, such as the left side in the first direction DR1. However, embodiments of the present disclosure are not necessarily limited thereto. For example, the scan driving unit SDR may be variously arranged and may also be disposed on both sides of the non-display area NDA in some embodiments. The scan driving unit SDR may be connected to a signal connection line CWL, and at least one end of the signal connection line CWL may be connected to an external device (“EXD” in FIG. 1) by forming a pad (WPD_CW) on the first non-display area NDA and/or the second non-display area NDA.

In an embodiment, the data line DTL and the reference voltage line RVL may extend in the second direction DR2 intersecting the first direction DR1. The first power supply line ELVDL may include a portion extending in the second direction DR2. The first power supply line ELVDL may further include a portion extending in the first direction DR1. In an embodiment, the first power supply line ELVDL may have a mesh structure. However, embodiments of the present disclosure are not necessarily limited thereto.

Wiring pads WPD may be disposed on at least one end of the data line DTL, the reference voltage line RVL, and the first power supply line ELVDL. Each wiring pad WPD may be disposed on a pad area PDA of the non-display area (NDA). In an embodiment, a wiring pad (WPD_DT, hereinafter referred to as a “data pad”) for a data line DTL, a wiring pad (WPD_RV, hereinafter referred to as a “reference voltage pad”) for the reference voltage line RVL, and a wiring pad (WPD_ELVD, hereinafter referred to as a “first power pad”) for a first power supply line ELVDL may be disposed on the pad area PDA of the non-display area NDA, such as on a lower side of the non-display area NDA in the second direction DR2. In another example, the data pad WPD_DT, the reference voltage pad WPD_RV, and the first power supply pad WPD_ELVD may be disposed in different non-display areas NDA. An external device (“EXD” in FIG. 1) may be mounted on the wiring pad WPD as described above. In an embodiment, the external device EXD may be mounted on the wiring pad WPD through an anisotropic conductive film, ultrasonic bonding, or the like.

Each pixel PX on the display board includes a pixel driving circuit. The wiring described above may pass through or around each pixel PX and apply a driving signal to each pixel driving circuit. The pixel driving circuit may include a transistor and a capacitor. The number of transistors and capacitors in each pixel driving circuit may be varied. Hereinafter, the pixel driving circuit will be described taking a 3T1C structure including three transistors and one capacitor as an example. However, embodiments of the present disclosure are not necessarily limited thereto, and various other modified pixel PX structures such as a 2T1C structure, a 7T1C structure, and a 6T1C structure may be applied.

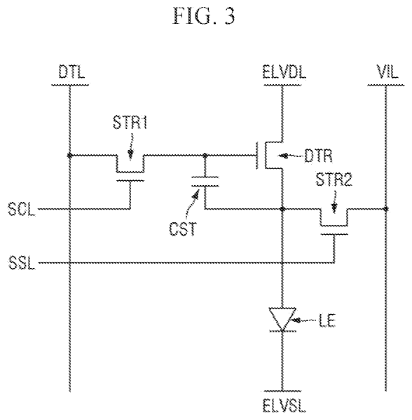

FIG. 3 is an equivalent circuit diagram of one pixel of a display device according to an embodiment.

Referring to FIG. 3, each pixel PX of the display device according to an embodiment includes, in addition to the light emitting element LE, three transistors DTR, STR1 and STR2 and one capacitor CST for storage.

The light emitting element LE emits light in response to a current supplied through a driving transistor DTR. In an embodiment, the light emitting element LE may be implemented as an inorganic light emitting diode, an organic light emitting diode, a micro light emitting diode, a nano light emitting diode, or the like.

In an embodiment, a first electrode (e.g., an anode electrode) of the light emitting element LE may be connected to a source electrode of the driving transistor DTR, and a second electrode (e.g., a cathode electrode) may be connected to a second power supply line ELVSL supplied with a low potential voltage (second power supply voltage) lower than a high potential voltage (first power supply voltage) of the first power supply line ELVDL.

The driving transistor DTR adjusts the current flowing to the light emitting element LE from the first power supply line ELVDL supplied with the first power voltage according to the voltage difference between a gate electrode and the source electrode. The gate electrode of the driving transistor DTR may be connected to the first electrode of the first transistor STR1, the source electrode may be connected to the first electrode of the light emitting element LE, and a drain electrode may be connected to the first power supply line ELVDL to which the first power supply voltage is applied.

A first transistor STR1 is turned-on by a scan signal on the scan line SCL to connect the data line DTL to the gate electrode of the driving transistor DTR. The gate electrode of the first transistor STR1 may be connected to the scan line SCL, the first electrode may be connected to the gate electrode of the driving transistor DTR, and the second electrode may be connected to the data line DTL.

A second transistor STR2 is turned-on by a sensing signal on the sensing signal line SSL to connect an initialization voltage line VIL to the source electrode of the driving transistor DTR. The gate electrode of the second transistor ST2 may be connected to the sensing signal line SSL, the first electrode may be connected to the initialization voltage line VIL, and the second electrode may be connected to the source electrode of the driving transistor DTR.

In an embodiment, the first electrode of each of the first and second transistors STR1 and STR2 may be the source electrode and the second electrode may be the drain electrode, but is not necessarily limited thereto, and may be vice versa.

The capacitor CST is formed between the gate and source electrodes of the driving transistor DTR. A storage capacitor CST stores the difference voltage between the gate voltage of the driving transistor DTR and the source voltage.

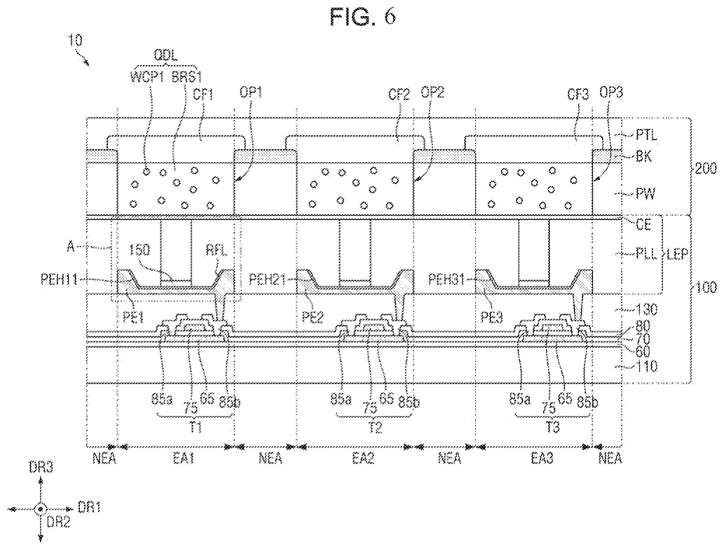

In an embodiment, the driving transistor DTR and the first and second transistors STR1 and STR2 may be formed as thin film transistors. Furthermore, while FIG. 6 describes the driving transistor DTR and the first and second switching transistors STR1 and STR2 as being N-type MOSFET (metal oxide semiconductor field effect transistors), embodiments of the present disclosure are not necessarily limited thereto. For example, in some embodiments the driving transistor DTR and the first and second switching transistors STR1 and STR2 may be P-type MOSFET, or some may be N-type MOSFET, and others may be P-type MOSFET.

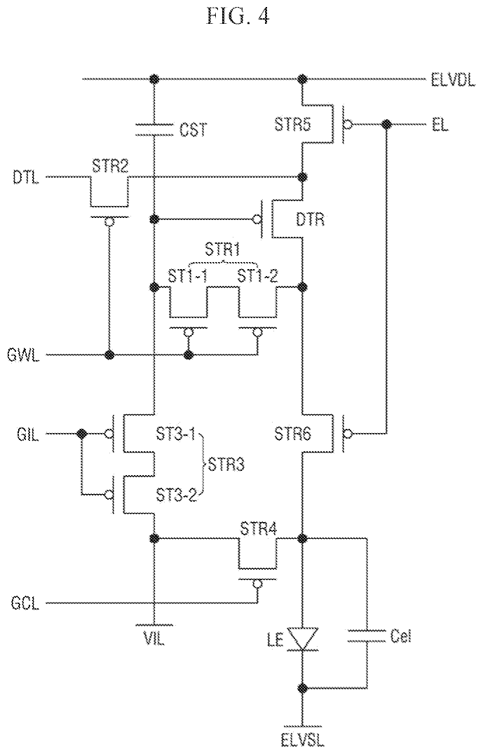

FIG. 4 is an equivalent circuit diagram of one pixel of a display device according to another embodiment.

Referring to FIG. 4, the first electrode of the light emitting element LE may be connected to the first electrode of the fourth transistor STR4 and the second electrode of the sixth transistor STR6, and the second electrode may be connected to the second power supply line ELVSL. A parasitic capacitance Cel may be formed between the first electrode and the second electrode of the light emitting element LE.

Each pixel PX includes the driving transistor DTR, switch elements, and the capacitor CST. In an embodiment, the switch elements include first to sixth transistors STR1, STR2, STR3, STR4, STR5, and STR6.

The driving transistor DTR includes the gate electrode, the first electrode, and the second electrode. The driving transistor DTR controls the drain-to-source current (hereinafter referred to as the “driving current”) flowing between the first and second electrodes based on the data voltage applied to the gate electrode.

The capacitor CST is formed between the second electrode of the driving transistor DTR and the second power supply line ELVSL. One electrode of the capacitor CST may be connected to the second electrode of the driving transistor DTR, and the other electrode may be connected to the second power supply line ELVSL.

In an embodiment in which the first electrode of each of the first to sixth transistors STR1, STR2, STR3, STR4, STR5, and STR6 and the driving transistor DTR is the source electrode, the second electrode may be the drain electrode. Alternatively, in an embodiment in which the first electrode of each of the first to sixth transistors STR1, STR2, STR3, STR4, STR5, and STR6 and the driving transistor DTR is the drain electrode, the second electrode may be the source electrode.

In an embodiment, an active layer of each of the first to sixth transistors STR1, STR2, STR3, STR4, STR5, and STR6 and the driving transistor DTR may be formed from any of poly silicon, amorphous silicon, and oxide semiconductors. However, embodiments of the present disclosure are not necessarily limited thereto. In an embodiment in which the semiconductor layer of each of the first through sixth transistors STR1, STR2, STR3, STR4, STR5, and STR6 and the driving transistor DTR is formed from poly silicon, the process for forming it may be a low temperature poly silicon (LTPS) process.

In addition, in FIG. 4, the first to sixth transistors STR1, STR2, STR3, STR4, STR5, and STR6 and the driving transistor DTR are described centering on the P-type MOSFET (Metal Oxide Semiconductor Field Effect Transistor). However, embodiments of the present disclosure are not necessarily limited thereto, and may be formed as the N-type MOSFET.

Further, the first power supply voltage of the first power supply line ELVDL, the second power supply voltage of the second power supply line ELVSL, and the third power supply voltage of the third power supply line VIL may be set by considering the characteristics of the driving transistor DTR, the characteristics of the light emitting element LE, or the like.

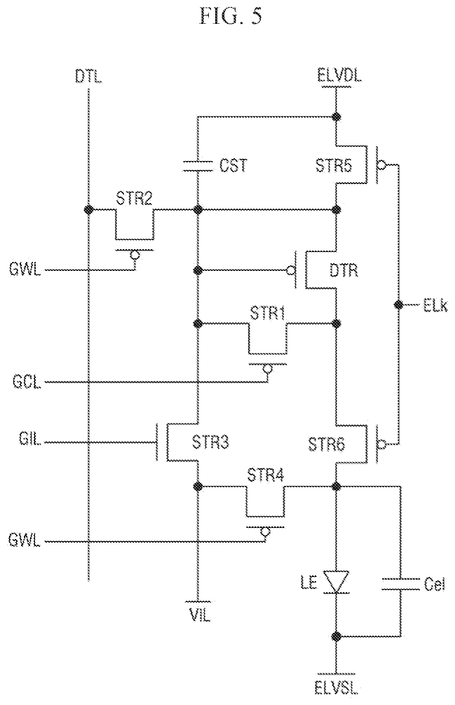

FIG. 5 is an equivalent circuit diagram of one pixel of a display device according to an embodiment.

The embodiment of FIG. 5 differs from the embodiment of FIG. 4 in that the driving transistor DTR, the second transistor STR2, the fourth transistor STR4, the fifth transistor STR5, and the sixth transistor STR6 are formed as the P-type MOSFET, and the first transistor STR1 and the third transistor STR3 are formed as the N-type MOSFET.

Referring to FIG. 5, in an embodiment the active layer of each of the driving transistor DTR, second transistor STR2, fourth transistor STR4, fifth transistor STR5, and sixth transistor STR6 formed as the P-type MOSFET may be formed of polysilicon, and the active layer of each of the first transistor STR1 and third transistor STR3 formed as the N-type MOSFET may be formed of an oxide semiconductor.

FIG. 5 differs from the embodiment of FIG. 4 in that the gate electrode of the second transistor STR2 and the gate electrode of the fourth transistor STR4 are connected to the write scan line GWL, and the gate electrode of the first transistor ST1 is connected to the control scan ling GCL. Also, in FIG. 5, the first transistor STR1 and the third transistor STR3 are formed as the N-type MOSFET, so that the scan signal of the gate high voltage may be applied to the control scan line GCL and the initialization scan line GIL. In an embodiment, since the second transistor STR2, the fourth transistor STR4, the fifth transistor STR5, and the sixth transistor STR6 are formed as the P-type MOSFET, the scan signal with a gate low voltage may be applied to the write scan wire GWL and the light emitting element LE.

It should be noted that the equivalent circuit diagram of a pixel according to an embodiment of the present disclosure described above is not necessarily limited to that shown in FIGS. 3 to 5. The equivalent circuit diagram of a pixel according to an embodiment of the present disclosure may be formed by other known circuit structures that may be employed by those skilled in the art other than embodiments shown in FIGS. 3 to 5.

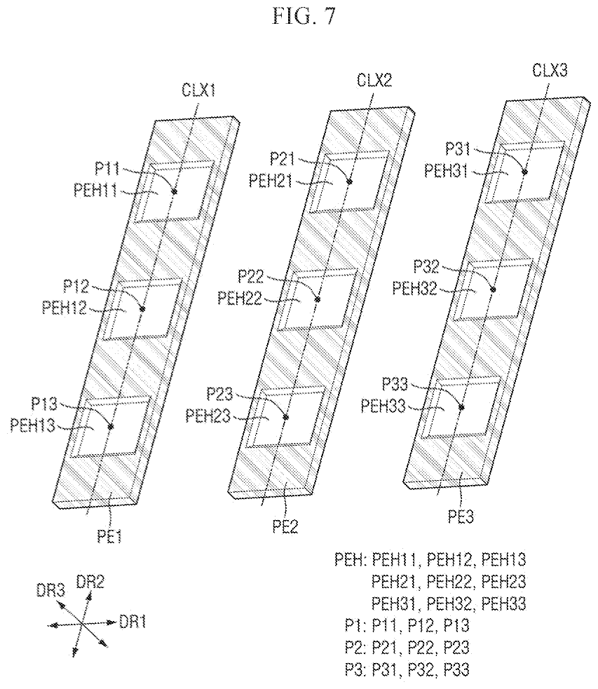

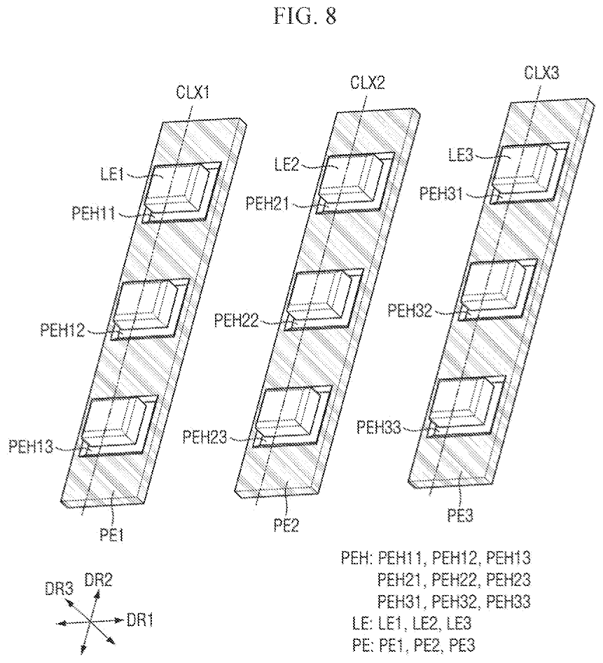

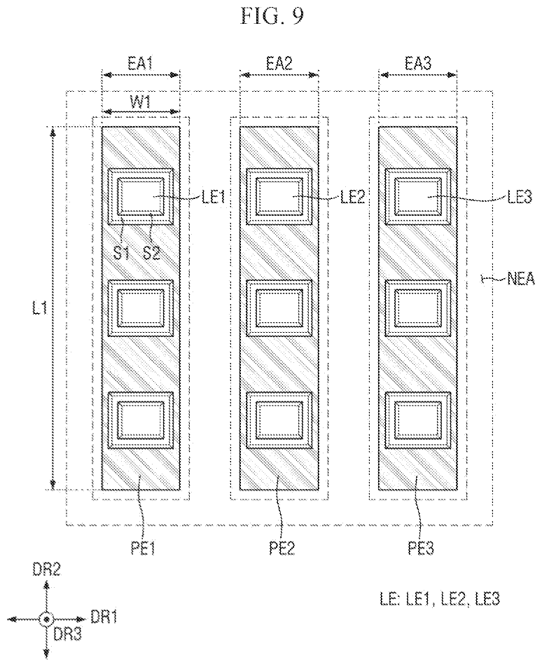

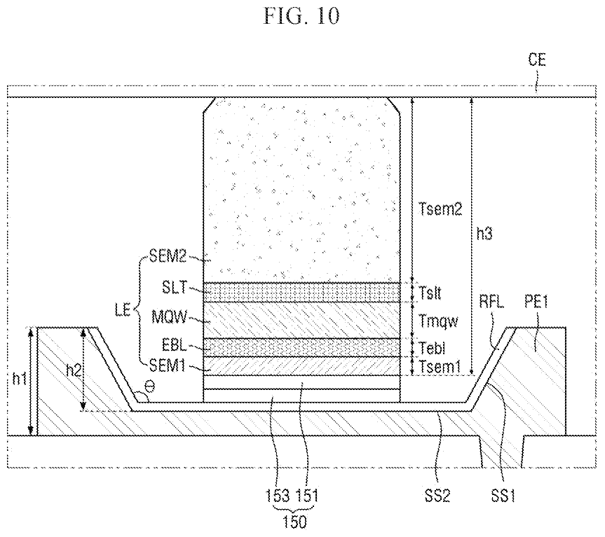

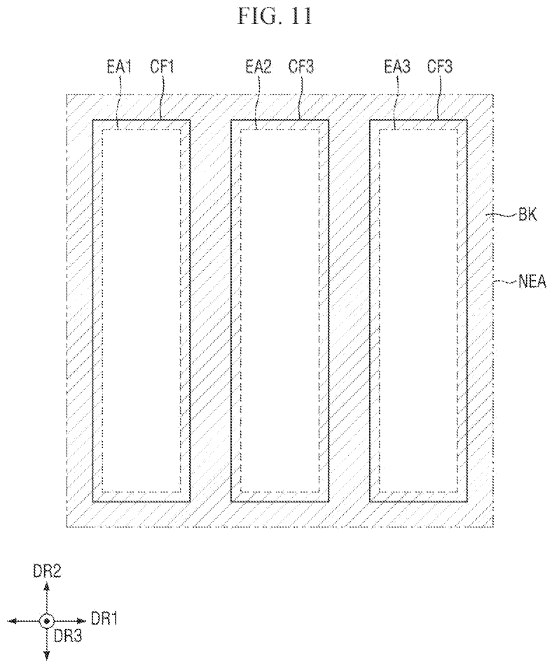

FIG. 6 is a cross-sectional view schematically illustrating a portion of a display area of the display device of FIG. 1. FIG. 7 is a perspective view illustrating a pixel electrode according to an embodiment. FIG. 8 is a perspective view illustrating a pixel electrode and a light emitting element of a display device according to an embodiment. FIG. 9 is a plan view of FIG. 8. FIG. 10 is an enlarged view of area A of FIG. 6. FIG. 11 is a plan view schematically illustrating the plurality of light emitting areas and a plurality of color filters.

Referring to FIGS. 6 to 11, the display device 10 may include a display substrate 100 and a wavelength conversion part 200 disposed on the display substrate 100 (e.g., in the third direction DR3).

The display substrate 100 may include a first substrate 110 and a light emitting element part LEP disposed on the first substrate 110. The first substrate 110 may be an insulating substrate. The first substrate 110 may include a transparent material. For example, in an embodiment the first substrate 110 may include a transparent insulating material such as glass, quartz, or the like. The first substrate 110 may be a rigid substrate. However, the first substrate 110 is not necessarily limited thereto and may include a plastic, such as polyimide, or the like. Also, the first substrate 110 may have flexible characteristics that allow it to be warped, bent, folded, or rolled. A plurality of emission areas, such as first to third emission areas EA1, EA2, and EA3 and non-emission areas NEA may be defined on the first substrate 110.

Switching elements, such as first to third switching elements T1, T2, and T3 may be disposed on the first substrate 110. In an embodiment, the first switching element T1 may be disposed in the first light emitting area EA1 of the first substrate 110, the second switching element T2 may be disposed in the second light emitting area EA2, and the third switching element T3 may be disposed in the third light emitting area EA3. However, embodiments of the present disclosure are not necessarily limited thereto, and at least one of the first switching element T1, the second switching element T2, and the third switching element T3 may be disposed in the non-emitting area NEA in some embodiments.

In an embodiment, the first switching element T1, the second switching element T2, and the third switching element T3 may each be a thin film transistor including an amorphous silicon, polysilicon, or oxide semiconductor. In an embodiment, there may be a plurality of signal lines (e.g., gate lines, data lines, power supply lines, etc.) further disposed on the first substrate 110 that carry signals to each switching element.

Each switching element of the first to third switching elements T1, T2, and T3 may include a semiconductor layer 65, a gate electrode 75, a source electrode 85a, and a drain electrode 85b. For example, a buffer layer 60 may be disposed on the first substrate 110. The buffer layer 60 may be disposed to cover a front side of the first substrate 110. In an embodiment, the buffer layer 60 may include a silicon nitride, a silicon oxide, or a silicon oxynitride, and may be a single layer or a double layer thereof. However, embodiments of the present disclosure are not necessarily limited thereto.

The semiconductor layer 65 may be disposed on the buffer layer 60 (e.g., disposed directly thereon). The semiconductor layer 65 may form a channel of each of the first to third switching elements T1, T2, and T3. In an embodiment, the semiconductor layer 65 may include amorphous silicon, polycrystalline silicon, or an oxide semiconductor. In one example, the oxide semiconductor, for example, may include a binary compound (ABx), a ternary compound (ABxCy), or a tetracyclic compound (ABxCyDz) containing indium, zinc, gallium, tin, titanium, aluminum, hafnium (Hf), zirconium (Zr), magnesium (Mg), or the like. In an embodiment, the semiconductor layer 65 may include indium tin zinc oxide (IGZO).

A gate insulating layer 70 may be disposed on the semiconductor layer 65 (e.g., disposed directly thereon). In an embodiment, the gate insulating layer 70 may include a silicon compound, a metal oxide, or the like. For example, the gate insulating layer 70 may include a silicon oxide, a silicon nitride, a silicon oxynitride, an aluminum oxide, a tantalum oxide, a hafnium oxide, a zirconium oxide, a titanium oxide, or the like. In an embodiment, the gate insulating layer 70 may include a silicon oxide.

The gate electrode 75 may be disposed on the gate insulating layer 70 (e.g., disposed directly thereon). The gate electrode 75 may overlap the semiconductor layer 65 (e.g., in the third direction DR3). The gate electrode 75 may include a conductive material. In an embodiment, the gate electrode 75 may include a metal oxide such as ITO, IZO, ITZO, In₂O₃, or a metal such as copper (Cu), titanium (Ti), aluminum (Al), molybdenum (Mo), tantalum (Ta), calcium (Ca), chromium (Cr), magnesium (Mg), or nickel (Ni). For example, the gate electrode 75 may be formed of a Cu/Ti double layer in which an upper layer of copper is stacked on a lower layer of titanium. However, embodiments of the present disclosure are not necessarily limited thereto.

An interlayer insulating layer 80 may be disposed on the gate electrode 75 (e.g., disposed directly thereon). In an embodiment, the interlayer insulating layer 80 may include an inorganic insulating material such as a silicon oxide, a silicon nitride, a silicon oxynitride, a hafnium oxide, an aluminum oxide, a titanium oxide, a tantalum oxide, a zinc oxide, or the like.

The source electrode 85a and a drain electrode 85b may be disposed on the interlayer insulating layer 80 (e.g., disposed directly thereon). The source electrode 85a and the drain electrode 85b may directly contact the semiconductor layer 65 through contact holes penetrating the interlayer insulating layer 80 and the gate insulating layer 70, respectively. In an embodiment, the source electrode 85a and the drain electrode 85b may include metal oxides such as ITO, IZO, ITZO, In₂O₃, or metals such as copper (Cu), titanium (Ti), aluminum (Al), molybdenum (Mo), tantalum (Ta), calcium (Ca), chromium (Cr), magnesium (Mg), and nickel (Ni). For example, the source electrode 85a and the drain electrode 85b may be formed of a Cu/Ti double layer in which an upper layer of copper is stacked on a lower layer of titanium. However, embodiments of the present disclosure are not necessarily limited thereto.

An insulating layer 130 may be disposed on (e.g., disposed directly thereon) the first switching element T1, the second switching element T2, and the third switching element T3. In an embodiment, the insulating layer 130 may be a planarization layer and may include an organic material. For example, in an embodiment the insulating layer 130 may include an acrylic-based resin, an epoxy-based resin, an imide-based resin, an ester-based resin, or the like. In an embodiment, the insulating layer 130 may include a positively photosensitive material or a negatively photosensitive material.

The light emitting element part LEP may be disposed on the insulating layer 130 (e.g., disposed directly thereon in the third direction DR3). In an embodiment, the light emitting element part LEP may include a plurality of pixel electrodes, such as first to third pixel electrodes PE1, PE2, and PE3, a plurality of light emitting elements LE, and a plurality of common electrodes, such as first and second common electrodes CE1 and CE2.

In an embodiment, the plurality of pixel electrodes may include a first pixel electrode PE1, a second pixel electrode PE2, and a third pixel electrode PE3. The first pixel electrode PE1, the second pixel electrode PE2, and the third pixel electrode PE3 may serve as the first electrode of the light emitting element LE and may be the anode electrode or the cathode electrode. The first pixel electrode PE1 may be disposed in the first light emitting area EA1, the second pixel electrode PE2 may be disposed in the second light emitting area EA2, and the third pixel electrode PE3 may be disposed in the third light emitting area EA3. In an embodiment, the first pixel electrode PE1 may fully overlap the first light emitting area EA1, the second pixel electrode PE2 may fully overlap the second light emitting area EA2, and the third pixel electrode PE3 may fully overlap the third light emitting area EA3. The first pixel electrode PE1 may be connected to the first switching element T1 by extending through the insulating layer 130, the second pixel electrode PE2 may be connected to the second switching element T2 by extending through the insulating layer 130, and the third pixel electrode PE3 may be connected to the third switching element T3 by extending through the insulating layer 130.

The first pixel electrode PE1, the second pixel electrode PE2, and the third pixel electrode PE3 may include a metal. In an embodiment, the metal may include, for example, copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. Also, the first pixel electrode PE1, the second pixel electrode PE2, and the third pixel electrode PE3 may have a multilayer structure in which two or more metal layers are stacked. For example, the first pixel electrode PE1, the second pixel electrode PE2, and the third pixel electrode PE3 may have a two-layer structure with a copper layer stacked on top of a titanium layer. However, embodiments of the present disclosure are not necessarily limited thereto. Further, the first pixel electrode PE1, the second pixel electrode PE2, and the third pixel electrode PE3 may be coated with a reflective material.

Referring to FIGS. 7 to 9, the first pixel electrode PE1, the second pixel electrode PE2, and the third pixel electrode PE3 may be arranged to be aligned with an arbitrary line extending in one direction, such as the second direction DR2. For example, the first to third pixel electrodes PE1, PE2, PE3 may be arranged in a matrix-column direction and spaced apart from each other at equal intervals. In an embodiment, the first pixel electrode PE1, the second pixel electrode PE2, and the third pixel electrode PE3 may have a rectangular shape with a relatively long side positioned in a vertical direction. However, embodiments of the present disclosure are not necessarily limited thereto, and the first to third pixel electrodes PE1, PE2, PE3 may have the rectangular shape with a relatively long side disposed in the vertical direction or may have the rhombic or circular shape. The size of the pixel electrodes may vary depending on the size of the pixel. For example, in an embodiment a pixel may have a size of about 78 μm*78 μm across and down. In such an embodiment, the pixel electrodes PE1, PE2, and PE3 may have a horizontal length W1 in a range of about 16-17 μm and a vertical length LI in a range of about 59-60 μm.

The first pixel electrode PE1, the second pixel electrode PE2, and the third pixel electrode PE3 may each have a plurality of grooves PEH. For example, in an embodiment the first pixel electrode PE1 may include a first groove PEH11, a second groove PEH12, and a third groove PEH13. The center P11 of the first groove PEH1 (e.g., in the first and second directions DR1, DR2), the center P12 of the second groove PEH2 (e.g., in the first and second directions DR1, DR2), and the center P13 of the third groove PEH3 (e.g., in the first and second directions DR1, DR2) are disposed on the long axis CLX1 of the first pixel electrode PE1.

Similarly, in an embodiment the second pixel electrode PE2 has a plurality of grooves, such as first to third grooves PEH21, PEH22, and PEH23, and the third pixel electrode PE3 has a plurality of grooves, such as the first to third grooves PEH31, PEH32, and PEH33. Also, the plurality of grooves, such as the first to third grooves PEH21, PEH22, and PEH23 of the second pixel electrode PE2 are disposed on the long axis CLX2 of the second pixel electrode PE2, and the plurality of grooves, such as the first to third grooves PEH31, PEH32, and PEH33 of the third pixel electrode PE3 are disposed on the long axis CLX3 of the third pixel electrode PE3.

Thus, the plurality of grooves PEH included in the same pixel electrode off the first to third pixel electrodes PE1, PE2, and PE3 may be arranged in a row on the long axis CLX1, CLX2, and CLX3. Also, the centers P1, P2, and P3 of the plurality of grooves PEH included in the same pixel electrode of the first to third pixel electrodes PE1, PE2, and PE3 may be arranged in a row on the long axis CLX1, CLX2, and CLX3. The planar shape of the grooves PEH may vary depending on the shape of the cutting surface perpendicular to the longitudinal direction of the light emitting element LE. For example, in an embodiment in which the cut surface of the light emitting element LE is square, the planar shape of the groove PEH may be square. In an embodiment in which the cut surface of the light emitting element LE is a circle, the plane shape of the groove PEH may be a circle.

An inclined surface SS1 and the bottom surface SS2 of the groove PEH are arranged with a reflective layer RFL made of the reflective material. The reflective material may be a material having a reflectivity of at least about 80% (e.g., greater than or equal to about 80%). For example, in an embodiment the reflective material may be Ag, Ni, Cr, or the like.

The area of the bottom surface SS2 of the groove PEH may be at least about 110% and no more than about 200% of the area of the first side of the light emitting element LE.

The inclined surface SS1 of the groove may have an arbitrary inclination angle θ. The inclination angle θ is the angle formed by the bottom surface SS2 of the groove and the inclined surface SS1, which may be in a range from about 90° to a maximum of about 160°.

A depth h2 of the groove PEH may range from about 10% to about 90% of the thickness h1 of the pixel electrodes PE1, PE2, and PE3. However, in an embodiment the depth h2 of the groove PEH may be higher than the height of an active layer MQW of the light emitting element LE disposed in the groove PEH. Therefore, in an embodiment, the reflective material is disposed on the inner surface of the groove PEH so that a portion of the light emitted from the active layer MQW of the light emitting elements LE1, LE2, and LE3 may be reflected upward from a reflective layer 151 of the light emitting element LE, and the remaining portion may proceed in a direction towards the pixel electrode PE1. In an embodiment, the light emitted from the light emitting element LE may be reflected upward to increase the light extraction efficiency by including the reflective layer RFL on the inclined surface SS1 of each of the first to third pixel electrodes PE1, PE2, and PE3.

In addition, in an embodiment, the light emitting element LE in the first light emitting area EA1 may emit blue first light having a center wavelength band in the range of 420 nm to 480 nm, the light emitting element LE of the second light emitting area EA2 may emit red second light having a center wavelength band in the range of 600 nm to 680 nm, the light emitting element LE of the third light emitting area EA3 may emit green third light having a center wavelength band in the range of 500 nm to 580 nm. The reflective layer RFL may reflect some of the light emitted by the light emitting element LE and emit it to a corresponding light emitting area. Thus, the reflective layer RFL can prevent light from being mixed between each of the first to third light emitting areas EA1, EA2, and EA3.

As shown in FIGS. 6 to 8, the light emitting elements LE may be disposed within the plurality of grooves PEH included in the first to third pixel electrodes PE1, PE2, and PE3.

Referring to FIGS. 8 and 9, in an embodiment three light emitting elements LE are disposed on one pixel electrode PE. However, embodiments of the present disclosure are not necessarily limited thereto and one or more light emitting elements LE may be disposed on one pixel electrode PE.

The light emitting elements LE may be disposed in each of the first emitting area EA1, the second emitting area EA2, and the third emitting area EA3. In an embodiment, the light emitting elements LE may be vertical light emitting diode elements extending in the third direction DR3. For example, the length of the light emitting elements LE in the third direction DR3 may be greater than the length in the horizontal direction. The length of the horizontal direction refers to the length of the first direction DR1 or the length of the second direction DR2. For example, in an embodiment the length of the third direction DR3 of the light emitting element LE may be in a range of about 1 μm to about 5 μm.

Referring to FIG. 10, the light emitting element LE may be a micro light emitting diode element. The light emitting element LE may include a connection electrode 150, a first semiconductor layer SEM1, an electronic blocking layer EBL, an active layer MQW, a superlattice layer SLT, and a second semiconductor layer SEM2 in the thickness direction of the display substrate 100, that is, the third direction DR3. The connection electrode 150, the first semiconductor layer SEM1, the electronic blocking layer EBL, the active layer MQW, the superlattice layer SLT, and the second semiconductor layer SEM2 may be stacked sequentially in the third direction DR3.

In an embodiment, the light emitting element LE may have a cylindrical, disk, or rod shape with a width that is greater than a height. However, embodiments of the present disclosure are not necessarily limited thereto. For example, in some embodiments the light emitting element LE may have a shape such as a rod, wire, tube, etc., a polygonal shape such as a cube, a rectangle, a hexagonal column, or a shape extending in one direction but having a partially inclined outer surface.

The connection electrode 150 may be disposed on top of each of the plurality of pixel electrodes PE1, PE2, and PE3 (e.g., in the third direction DR3). The following describes the light emitting element LE disposed on the first pixel electrode PE1 as an example, but is not necessarily limited thereto, and the structure of the light emitting element LE disposed on the second pixel electrode PE2 and the third pixel electrode PE3 may be similarly configured.

The connection electrode 150 may include the reflective layer 151 and a connection layer 153. The reflective layer 151 may reflect light emitted from the active layer MQW of the light emitting element LE. The reflective layer 151 may be disposed adjacent to the active layer MQW of the light emitting element LE. The reflective layer 151 may include a metallic material that is conductive and highly reflective of light. For example, in an embodiment the reflective layer 151 may include aluminum (Al) or silver (Ag), and may be an alloy thereof.

The connection layer 153 may serve to transmit an emission signal from the first pixel electrode PE1 to the light emitting element LE. The connection layer 153 may be an Ohmic connection electrode. However, the connection layer 153 may also be a Schottky connection electrode in some embodiments. The connection layer 153 may be disposed at the bottom end of the light emitting element LE and may be disposed farther from the active layer MQW than the reflective layer 151 (e.g. in the third direction DR3). In an embodiment, the connection layer 153 may include at least one of gold (Au), copper (Cu), tin (Sn), silver (Ag), aluminum (Al), and titanium (Ti). For example, the connection layer 153 may include a 9:1 alloy of gold and tin, an 8:2 alloy, or a 7:3 alloy, or may include an alloy of copper, silver, and tin (SAC305). However, embodiments of the present disclosure are not necessarily limited thereto.

FIG. 10 illustrates a connection electrode 150 where the light emitting element LE is a double-layer structure comprised of a single reflective layer 151 and the connection layer 153. However, embodiments of the present disclosure are not necessarily limited thereto. For example, in some embodiments the light emitting element LE may include the connection electrode 150 with a greater number of layers stacked on it, or some layers may be omitted.

The first semiconductor layer SEM1 may be disposed on the connection electrode 150 (e.g., disposed directly thereon in the third direction DR3). In an embodiment, the first semiconductor layer SEM1 may be a p-type semiconductor and may include a semiconductor material having a chemical formula of AlxGayIn1-x-yN (0≤x≤1, 0≤y≤1, 0≤x+y≤1). For example, in some embodiments the first semiconductor layer SEM1 may be one or more of p-type doped AlGaInN, GaN, AlGaN, InGaN, AlN, and InN. The first semiconductor layer SEM1 may be doped with a p-type dopant, and the p-type dopant may be Mg, Zn, Ca, Se, Ba, or the like. For example, the first semiconductor layer SEM1 may be p-GaN doped with p-type Mg. The thickness of the first semiconductor layer SEM1 may be in a range from about 30 nm to about 200 nm. However, embodiments of the present disclosure are not necessarily limited thereto.

The electronic blocking layer EBL may be disposed on the first semiconductor layer SEM1 (e.g., disposed directly thereon in the third direction DR3). The electronic blocking layer EBL may be a layer to suppress or prevent too many electrons from flowing into the active layer MQW. For example, in an embodiment the electronic blocking layer EBL may be p-AlGaN doped with p-type Mg. In an embodiment, the thickness of the electronic blocking layer EBL may be in a range from about 10 nm to about 50 nm. However, embodiments of the present disclosure are not necessarily limited thereto. Additionally, the electronic blocking layer EBL may be omitted in some embodiments.

The active layer MQW may be disposed on the electronic blocking layer EBL (e.g., disposed directly thereon in the third direction DR3). The active layer MQW may emit light by coupling of electron-hole pairs in response to an electrical signal applied through the first semiconductor layer SEM1 and the second semiconductor layer SEM2. In an embodiment the active layer MQW may emit first light having a central wavelength range of 450 nm to 495 nm, that is, light in a blue wavelength band.

The active layer MQW may include a single or multiple quantum well structure. In an embodiment in which the active layer MQW includes a material with a multi-quantum well structure, the active layer MQW may be a stacked structure with a plurality of well layers and a barrier layer alternating with each other. In this embodiment, the well layer may be formed of InGaN and the barrier layer may be formed of GaN or AlGaN. However, embodiments of the present disclosure are not necessarily limited thereto. In an embodiment, the thickness of the well layer may be in a range of about 1 to about 4 nm, and the thickness of the barrier layer may be in a range of about 3 nm to about 10 nm.

Alternatively, the active layer MQW may have a structure in which a semiconductor material having a large band gap energy and a semiconductor material having a small band gap energy are alternately stacked with each other and may include other Group 3 to Group 5 semiconductor materials depending on the wavelength band of the emitted light. The light emitted by the active layer MQW is not necessarily limited to the first light, and in some cases, the second light (e.g., light of the green wavelength band) or the third light (e.g., light of the red wavelength band) may be emitted by the active layer MQW. In an embodiment in which the semiconductor material included in the active layer MQW includes indium, the color of the emitted light may vary depending on the content of indium. For example, a decrease in the amount of indium may shift the wavelength band of the emitted light to a red wavelength band, and an increase in the amount of indium may shift the wavelength band of the emitted light to a blue wavelength band.

In an embodiment, the superlattice layer SLT may be disposed on the active layer MQW (e.g., disposed directly thereon in the third direction DR3). The superlattice layer SLT may be a layer for relieving stress between the second semiconductor layer SEM2 and the active layer MQW. For example, the superlattice layer SLT may be formed of InGaN or GaN. In an embodiment, a thickness of the superlattice layer SLT may be in a range of about 50 to about 200 nm. In some embodiments, the superlattice layer SLT may be omitted.

In an embodiment the second semiconductor layer SEM2 may be disposed on the superlattice layer SLT1 (e.g., disposed directly thereon in the third direction DR3). The second semiconductor layer SEM2 may be a n-type semiconductor. In an embodiment, the second semiconductor layer SEM2 may include a semiconductor material having a chemical formula of AlxGayIn1-x-yN (0≤x≤1, 0≤y≤1, 0≤x+y≤1). For example, the second semiconductor layer SEM2 may be one or more of n-type doped AlGaInN, GaN, AlGaN, InGaN, AlN, and InN. The second semiconductor layer SEM2 may be doped with an n-type dopant, and the n-type dopant may be Si, Ge, Sn, or the like. For example, the second semiconductor layer SEM2 may be n-GaN doped with n-type Si. The thickness of the second semiconductor layer SEM2 may be in a range of about 2 μm to about 4 μm. However, embodiments of the present disclosure are not necessarily limited thereto.

Referring to FIG. 6, the plurality of pixel electrodes, such as the first to third pixel electrodes PE1, PE2, and PE3 and a planarization layer PLL may be disposed on the insulating layer 130 on which the first to third pixel electrodes PE1, PE2, and PE3 are not disposed. The planarization layer PLL may be disposed (e.g., filled) between the light emitting elements LE. The planarization layer PLL may flatten a lower step so that a common electrode CE described later may be formed.

A planarization layer PPL may include the organic material to planarize the lower step. For example, in an embodiment the planarization layer PPL may include a polyacrylates resin, an epoxy resin, a phenolic resin, a polyamides resin, or a polyimides rein, unsaturated polyester resin, poly phenylenethers resin, polyphenylenesulfides resin, or benzocyclobutene (BCB).

The common electrode CE may be disposed on the planarization layer PLL and the plurality of light emitting elements LE. For example, in an embodiment the common electrode CE is disposed on one side of the first substrate 110 on which the light emitting elements LE are formed and may be disposed throughout the display area DPA and the non-display area NDA. The common electrode CE is disposed overlapping each of the first to third light emitting areas EA1, EA2, and EA3 in the display area DPA, and may be made of a relatively small thickness so that light may be emitted. For example, in an embodiment the common electrode CE may have a thickness in a range of about 10 Å to about 200 Å. However, embodiments of the present disclosure are not necessarily limited thereto.

The common electrode CE may be disposed directly on the tops and sides of the plurality of light emitting elements LE. The common electrode CE may be in direct contact with the second semiconductor layer SEM2. As shown in FIG. 6, the common electrode CE covers the plurality of light emitting elements LE and may be a common layer disposed in common connection with the plurality of light emitting elements LE. Since the conductive second semiconductor layer SEM2 is patterned on each of the light emitting elements LE, a common voltage may be applied to each light emitting element LE through the common electrode CE.

The common electrode CE may include a material that is disposed throughout the first substrate 110 and has a low resistance due to the common voltage being applied. For example, in an embodiment the common electrode CE may include a material having the low resistance, such as aluminum (Al), silver (Ag), copper (Cu), or the like.

The light emitting elements LE described above may be supplied with a pixel voltage or an anode voltage from each of the first to third pixel electrodes PE1, PE2, and PE3 and a common voltage through the common electrode CE. The light emitting elements LE may emit light at a predetermined luminance depending on the voltage difference between the pixel voltage and the common voltage.

Although the configuration in which the common electrode CE is commonly disposed in a plurality of pixels has been exemplified in the above-described embodiment, embodiments of the present disclosure are not necessarily limited thereto, and a configuration in which a separate common connection electrode is disposed for each pixel may be implemented in some embodiments. In such a case, the configuration of the light emitting element LE and the common electrode of the light emitting area in each pixel is similar to that described with reference to FIG. 4, FIG. 8, or FIG. 10, so a detailed description thereof will be omitted.

In the present embodiment, the first to third pixel electrodes PE1, PE2, and PE3 have the groove PEH, and the misalignment error of the light emitting elements LE may be reduced by disposing the light emitting elements LE in the groove PEH. Accordingly, the light emitting element LE may be prevented from protruding outwardly from the first to third pixel electrodes PE1, PE2, and PE3 in a plane.

In a comparative embodiment in which the light emitting element LE protrudes outwardly from the first to third pixel electrodes PE1, PE2, and PE3 and is partially adhered to the sides, crosstalk between pixels may occur.

On the other hand, a wavelength conversion part 200 may be disposed on the light emitting element part LEP. In an embodiment, the wavelength conversion part 200 may include a partition wall PW, a wavelength conversion layer QDL, first to third color filters CF1, CF2, and CF3, a light blocking member BK, and a protective layer PTL.

Partition walls PW are disposed on the common electrode CE of the display area DPA and may compartmentalize the plurality of light emitting areas, such as the first to third light emitting areas EA1, EA2, and EA2. In an embodiment, the partition walls PW are arranged to extend in the first direction DR1 and the second direction DR2 and may be arranged in a grid-like pattern throughout the display area DPA. Furthermore, the partition wall PW may be non-overlapping with the plurality of light emitting areas, such as the first to third light emitting areas EA1, EA2, and EA3, and overlapping with the non-emitting area NEA.

In an embodiment, the partition wall PW may include a plurality of openings, such as first to third openings OP1, OP2, and OP3 exposing the lower common electrode CE. The plurality of openings may include a first opening OP1 overlapping the first emitting area EA1, a second opening OP2 overlapping the second emitting area EA2, and a third opening OP3 overlapping the third emitting area EA3. Here, the first to third openings OP1, OP2, and OP3 may correspond to the first to third light emitting areas EA1, EA2, and EA3, such that the first opening OP1 corresponds to the first light emitting area EA1, the second opening OP2 corresponds to the second light emitting area EA2, and the third opening OP3 corresponds to the third light emitting area EA3.

The partition wall PW may provide a space for the wavelength conversion layer QDL to be formed. In an embodiment, the partition wall PW may have a predetermined thickness, for example, the partition wall PW may have a thickness in the range of about 1 μm to about 10 μm. In an embodiment, the partition wall PW may include an organic insulating material to achieve the predetermined thickness of the partition wall PW. In an embodiment, the organic insulating material may include, for example, an epoxy-based resin, an acrylic-based resin, a cado-based resin, or an imide-based resin. However, embodiments of the present disclosure are not necessarily limited thereto.

The wavelength conversion layer QDL may be disposed on each of the plurality of openings, such as the first to third openings OP1, OP2, and OP3. The wavelength conversion layer QDL may convert or shift the peak wavelength of the incident light into light of a different specific peak wavelength. The wavelength conversion layer QDL may convert a portion of the blue first light emitted from the light emitting element LE into yellow fourth light. The wavelength conversion layer QDL may mix the first light and the fourth light to emit a white fifth light. The fifth light may be converted to the first light through a first color filter CF1, converted to the second light through a second color filter CF2, and converted to the third light through a third color filter CF3.

The wavelength conversion layers QDL may be disposed within each of the plurality of openings, such as the first to third openings OP1, OP2, and OP3 and may be spaced apart from each other. For example, in an embodiment the wavelength conversion layers QDL may include a dot-shaped island pattern spaced apart from each other. For example, the wavelength conversion layers QDL may be disposed at the first opening OP1, the second opening OP2, and the third opening OP3, respectively, and may correspond to them one-to-one. Further, the wavelength conversion layer QDL may be disposed in the first light emitting area EA1, the second light emitting area EA2, and the third light emitting area EA3, respectively, overlappingly. In an embodiment, each of the wavelength conversion layers QDL may be fully overlapped with the first light emitting area EA1, the second light emitting area EA2, and the third light emitting area EA3.

In an embodiment, the wavelength conversion layer QDL may include a first base resin BRS1 and a first wavelength conversion particle WCP1. The first base resin BRS1 may include a light-transmissive organic material. For example, in an embodiment the first base resin BRS1 may include an epoxy-based resin, an acrylic-based resin, a cado-based resin, or an imide-based resin. However, embodiments of the present disclosure are not necessarily limited thereto.

The first wavelength conversion particle WCP1 may convert the first light incident on the light emitting element LE into the fourth light. For example, the first wavelength conversion particle WCP1 may convert light in the blue wavelength band to light in the yellow wavelength band. In an embodiment, the first wavelength conversion particle WCP1 may be a quantum dot QD, a quantum rod, a fluorescent material, or a phosphor. For example, the quantum dot may be a particulate material that emits a specific color as electrons transition from conduction to valence.

The quantum dots may be semiconductor nanocrystalline materials. Depending on its composition and size, the quantum dot may have a specific bandgap to absorb light and emit light with a unique wavelength. Examples of the semiconductor nanocrystals of the quantum dots include IV group nanocrystals, II-VI group compound nanocrystals, III-V group compound nanocrystals, IV-VI group nanocrystals, or combinations thereof.

In an embodiment, the group II-VI compound is a binary compound selected from the group consisting of CdSe, CdTe, ZnS, ZnSe, ZnTe, ZnO, HgS, HgSe, HgTe, MgSe, MgS, and mixtures thereof; InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and ternary compounds selected from the group consisting of mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

In an embodiment, the group III-V compound is a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, and mixtures thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

In an embodiment, the group IV-VI compounds may be selected from the group consisting of binary compounds selected from the group consisting of SnS, SnSe, SnTe, PbS, PbSe, PbTe, and mixtures thereof; ternary compounds selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. The group IV element may be selected from the group consisting of Si, Ge, and mixtures thereof. The group IV compound may be a binary compound selected from the group consisting of SiC, SiGe, and mixtures thereof.

The binary, ternary, or quaternary compounds may be present in the particle at a uniform concentration or may be present in the same particle with a partially different concentration distribution. In an embodiment, the quantum dot may also have a core/shell structure in which one quantum dot surrounds another. The interface of the core and shell may have a concentration gradient in which the concentration of an element present in the shell decreases towards the center.

In an embodiment, the quantum dot may have a core-shell structure including a core including a nanocrystal as described above and a shell surrounding the core. The shell of the quantum dot may act as a protective layer to prevent chemical denaturation of the core to maintain semiconductor properties and/or as a charging layer to impart electrophoretic properties to the quantum dot. The shell may be monolayer or multilayer. Examples of shells for the quantum dots include oxides of metals or non-metals, semiconductor compounds, or combinations thereof. However, embodiments of the present disclosure are not necessarily limited thereto.

For example, in an embodiment the oxides of said metals or non-metals may be binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or ternary compounds such as MgAl₂O₄, CoFe₂O₄, NiFe₂O₄, CoMn₂O₄. However, embodiments of the present disclosure are not necessarily limited thereto.

In addition, in an embodiment the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc. However, embodiments of the present disclosure are not necessarily limited thereto.

The wavelength conversion layer QDL may further include a scatterer for scattering light from the light emitting element LE in a random direction. The scatterer may have a different refractive index than the first base resin BRS1 and form an optical interface with the first base resin BRS1. For example, the scatterer may be a light scattering particle. The scatterer is not particularly limited to any material capable of scattering at least a portion of the transmitted light, but may be, for example, a metal oxide particle or an organic particle. Examples of metal oxides include titanium oxide (TiO₂), zirconium oxide (ZrO₂), aluminum oxide (Al₂O₃), indium oxide (In₂O₃), zinc oxide (ZnO), or tin oxide (SnO₂), and examples of organic particle materials include acrylic resins or urethane resins. The scatterer is capable of scattering light in the random direction independent of the incident direction of the incident light without substantially changing the wavelength of the light.

As thickness of the wavelength conversion layer QDL in the third direction DR3 increases, the content of the first wavelength conversion particle WCP1 contained in the wavelength conversion layer QDL increases which may increase the light conversion efficiency of the wavelength conversion layer QDL. Therefore, the thickness of the wavelength conversion layer QDL maybe determined by considering the light conversion efficiency of the wavelength conversion layer QDL.

In the wavelength conversion part 200 described above, a portion of the first light emitted by the light emitting element LE may be converted to the fourth light in the wavelength conversion layer QDL. In the wavelength conversion layer QDL, the first light and the fourth light may be mixed to emit the white fifth light. The fifth light emitted from the wavelength conversion layer QDL may transmit only the first light from the first color filter CF1 only the second light from the second color filter CF2, and only the third light from the third color filter CF3 described later. Accordingly, the light emitted from the wavelength conversion part 200 may be blue, red, and green light of the first light, the second light, and the third light, thereby enabling full color to be realized.

The plurality of color filters, such as the first to third color filters CF1, CF2, and CF3 may be disposed on the partition wall PW and the wavelength conversion layer QDL. The plurality of color filters, such as the first to third color filters CF1, CF2, and CF3 may be stacked with the plurality of openings, such as the first to third openings OP1, OP2, and OP3 and the wavelength conversion layer QDL. The plurality of color filters may include the first color filter CF1, the second color filter CF2, and the third color filter CF3.

In an embodiment, the first color filter CF1 may be disposed in overlap with the first emitting area EA1 and may be partially overlapped with the non-emitting area NEA. Also, the first color filter CF1 may be disposed on the first opening OP1 of the partition wall PW to overlap with the first opening OP1, and may be partially overlapped with the light blocking member BK. The first color filter CF1 may transmit the first light emitted by the light emitting element LE and may absorb or block the second light and the third light. For example, the first color filter CF1 may transmit light in the blue wavelength band and absorb or block light in other wavelength bands such as green, red, etc.

In an embodiment, the second color filter CF2 may be disposed in overlap with the second emitting area EA2, and a portion of the second color filter CF2 may overlap with the non-emitting area NEA. Also, the second color filter CF2 may be disposed on the second opening OP2 of the partition wall PW to overlap with the second opening OP2, and may be partially overlapped with the light blocking member BK. The second color filter CF2 may transmit the second light and may absorb or block the first light and the third light. For example, the second color filter CF2 may transmit light in the green wavelength band and absorb or block light in other wavelength bands such as blue, red, etc.

The third color filter CF3 may be disposed to overlap with the third emitting area EA3, and a portion of the third color filter CF3 may overlap with the non-emitting area NEA. Also, the third color filter CF3 may be disposed on the third opening OP3 of the partition wall PW to overlap with the third opening OP3, and may be partially overlapped with the light blocking member BK. The third color filter CF3 may transmit the third light and may absorb or block the first light and the second light. For example, the third color filter CF3 may transmit light in the red wavelength band and absorb or block light in the blue, green, or other wavelength band.

As shown in FIG. 11, a planar area of each of the plurality of color filters, such as the first to third color filters CF1, CF2, and CF3 may be larger than a planar area of each of the plurality of light emitting areas, such as the first to third light emitting areas EA1, EA2, and EA3. For example, the first color filter CF1 may be larger than the planar area of the first emitting area EA1. The second color filter CF2 may be larger than the planar area of the second emitting area EA2. The third color filter CF3 may be larger than the planar area of the third light emitting area EA3. However, embodiments of the present disclosure are not necessarily limited thereto and the planar area of each of the first to third color filters CF1, CF2, and CF3 may be equal to the planar area of each of the first to third light emitting areas EA1, EA2, and EA3.

Referring again to FIG. 6, the light blocking member BK may be disposed on the partition wall PW. For example, in an embodiment the light blocking member BK may be disposed directly on an upper surface of the partition wall PW (e.g., in the third direction DR3). The light blocking members BK may overlap the non-emitting area NEA to block light transmission. In an embodiment, the light blocking members BK may be arranged in a roughly grid-like configuration in a plan view, similar to the partition wall PW. The light blocking members BK may be arranged overlapping with the partition wall PW and non-overlapping with the first to third light emitting areas EA1, EA2, and EA3.

In an embodiment, the light blocking member BK may include an organic light blocking material and may be formed through a coating and exposure process of the organic light blocking material. The light blocking member BK may include a dye or pigment having light blocking properties and may be a black matrix. The light blocking member BK may overlap at least partially with adjacent first to third color filters CF1, CF2, and CF3, and the first to third color filters CF1, CF2, and CF3 may be disposed on at least portion of the light blocking member BK.

External light incident on the display device 10 from the outside may cause a problem of distorting the color gamut of the wavelength conversion part 200. In an embodiment in which the light blocking member BK is disposed on the wavelength conversion part 200, at least a portion of the external light is absorbed by the light blocking member BK. Thus, color distortion due to reflection of the external light may be reduced. Furthermore, the light blocking member BK may prevent light from intruding between adjacent light emitting areas and causing color mixing, thereby further increasing the color reproduction rate.

The protective layer PTL may be disposed on the plurality of color filters, such as the first to third color filters CF1, CF2, and CF3 and the light blocking member BK. The first protective layer PTL may be disposed at the uppermost portion of the display device 10 to protect the plurality of color filters, such as the first to third color filters CF1, CF2, and CF3 and the light blocking member BK at the bottom. One side, for example, the lower surface of the of the protective layer PTL may directly contact the upper surface of the plurality of color filters, such as the first to third color filters CF1, CF2, and CF3 and the light blocking member BK, respectively.

In an embodiment, the protective layer PTL may include an inorganic insulating material to protect the plurality of color filters, such as the first to third color filters CF1, CF2, and CF3 and the light blocking member BK. For example, in an embodiment the first protective layer PTL may include silicon oxide (SiOx), silicon nitride (SiNx), silicon oxynitride (SiOxNy), aluminum oxide (AlxOy), aluminum nitride (AlN), or the like. However, embodiments of the present disclosure are not necessarily limited thereto. The first protective layer PTF1 may have a predetermined thickness, for example, in the range of about 0.01 μm to about 1 μm. However, embodiments of the present disclosure are not necessarily limited thereto.

As described above, the display device 10 according to an embodiment may prevent panel defects by disposing the light emitting elements LE in the grooves PEH formed within each of the first to third pixel electrodes PE1, PE2, and PE3, thereby preventing at least a portion of the light emitting elements LE from leaving (e.g., protruding from) a first side of the first to third pixel electrodes PE1, PE2, and PE3.

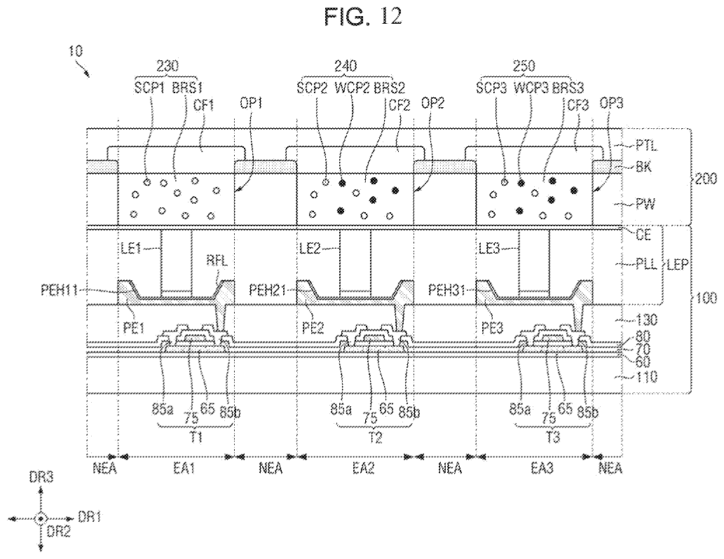

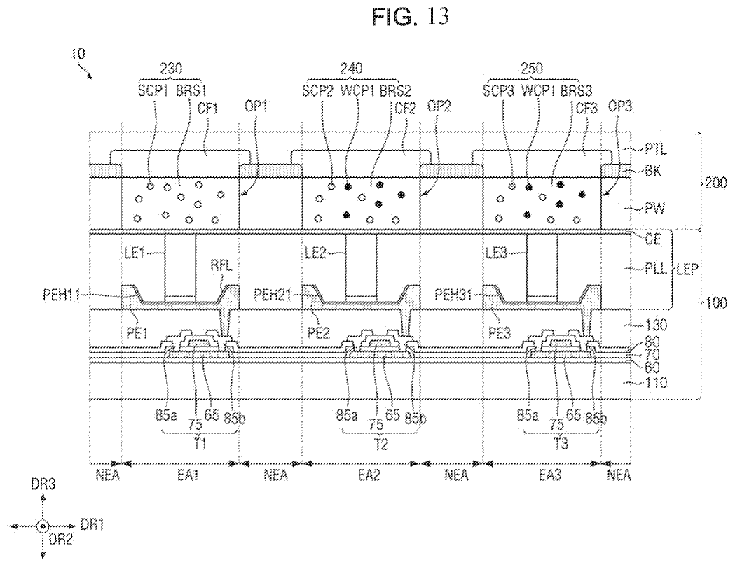

FIG. 12 is a cross-sectional view schematically illustrating a display device according to an embodiment. FIG. 13 is a schematic cross-sectional view of a display device according to an embodiment.

Referring to FIGS. 12 and 13, in this embodiment, the wavelength conversion layer QDL is different from the embodiment of FIG. 6 described above. Hereinafter, a description of similar or identical elements as previously described will be briefly described or omitted, and the differences will be described in detail for economy of description.

Referring to FIG. 12, in an embodiment, the light emitting elements LE disposed in the first light emitting area EA1, the second light emitting area EA2, and the third light emitting area EA3, respectively, may emit the first light of blue color. In this embodiment, the wavelength conversion layer QDL may include a light transmission pattern 230 overlapping the first light emitting area EA1, a first wavelength conversion pattern 240 overlapping the second light emitting area EA2, and a second wavelength conversion pattern 250 overlapping the third light emitting area EA3.

The light transmission pattern 230 may be disposed within the first opening OP1 and may be disposed overlapping the first light emitting area EA1 and the first color filter CF1. The light transmission pattern 230 may transmit incident light. The first light emitted by the light emitting element LE disposed in the first light emitting area EA1 may be blue light. The first light, which is blue light, may be transmitted through the light transmission pattern 230 and emitted from the first light emitting area EA1. In an embodiment, the light transmission pattern 230 may include the first base resin BRS1 and a first scatterer SCP1 dispersed in the first base resin BRS1. The first base resin BRS1 and the scatterer are described above.

The first wavelength conversion pattern 240 may be disposed within the second opening OP2 and may overlap with the second emitting area EA2 and the second color filter CF2. The first wavelength conversion pattern 240 may convert or shift a peak wavelength of incident light into light of a different specific peak wavelength. In an embodiment, the first wavelength conversion pattern 240 may convert and emit first light emitted by the light emitting element LE in the second emitting area EA2 into second light that is red light having a single peak wavelength in the range of about 610 nm to about 650 nm.

In an embodiment, the first wavelength conversion pattern 240 may include the second base resin BRS2 and second wavelength conversion particles WCP2 and second scatterers SCP2 dispersed within the second base resin BRS2.

In an embodiment, the second base resin BRS2 may be made of a material having high light transmittance and may be made of the same material as the first base resin BRS1 described above.

The second wavelength conversion particle WCP2 may convert or shift the peak wavelength of the incident light to another specific peak wavelength. In an embodiment, the second wavelength conversion particle WCP2 may convert light of the first color, which is blue light provided by the light emitting element LE, into light of the third color, which is red light having a single peak wavelength in the range from about 610 nm to about 650 nm and emit it. Examples of the second wavelength conversion particle WCP2 include quantum dots, quantum rods, or phosphors. A more specific description of the second wavelength conversion particle WCP2 is substantially the same or similar to that described above for the first wavelength conversion particle WCP1 and will be omitted.

Some of the first light, which is blue light, emitted by the light emitting element LE may be transmitted through the first wavelength conversion pattern 240 without being converted into second light, which is red light, by the second wavelength conversion particle WCP2. However, the light that is not converted to red light may be blocked by the second color filter CF2. On the other hand, the red light converted by the first wavelength conversion pattern 240 of the first light emitted by the light emitting element LE is transmitted through the second color filter CF2 and emitted to the outside.

The second wavelength conversion pattern 250 may be disposed within the third opening OP3 and may overlap with the third emitting area EA3 and the third color filter CF3. The second wavelength conversion pattern 250 may convert or shift the peak wavelength of the incident light into light of a different specific peak wavelength. In an embodiment, the second wavelength conversion pattern 250 may convert the first light emitted by the light emitting element LE of the third emitting area EA3 into green colored third light having a peak wavelength in the range of about 510 nm to 550 nm and emit it.

The second wavelength conversion pattern 250 may include a third base resin BRS3 and third wavelength conversion particles WCP3 and third scatterers SCP3 dispersed in the third base resin BRS3.

In an embodiment, the third base resin BRS3 may be made of a material with high light transmittance and may be made of the same material as the first base resin BRS1, the second base resin BRS2, and the third base resin BRS3, or may include at least one of the materials described as a component material thereof.

The third wavelength conversion particle WCP3 may convert or shift a peak wavelength of incident light to another specific peak wavelength. In an embodiment, the third wavelength conversion particle WCP3 may convert the first light, which is blue light provided by the light emitting element LE, into green third light having a peak wavelength in the range of about 510 nm to 550 nm and emit it.

Examples of the third wavelength conversion particle WCP3 include quantum dots, quantum rods, or phosphors. A more specific description of the third wavelength conversion particle WCP3 is substantially the same or similar to that described above for the first wavelength conversion particle WCP1 and will be omitted.

Some of the first light, which is blue light emitted by the light emitting element LE, may not be converted to third light, which is green light, by the third wavelength conversion particle WCP3. However, the first light that is not converted to green light may be blocked by the third color filter CF3 disposed on the top. On the other hand, the green light converted by the second wavelength conversion pattern 250 passes through the third color filter CF3 and is emitted to the outside.

The display device 10 according to the above-described embodiment may increase the light emission efficiency of blue, green, and red light by forming the wavelength conversion layer QDL including the light transmission pattern 230, the first wavelength conversion pattern 240, and the second wavelength conversion pattern 250.

Referring to FIG. 13, in an embodiment, the first wavelength conversion pattern 240 and the second wavelength conversion pattern 250 differ from the embodiment of FIG. 12 described above in that each includes the first wavelength conversion particle WCP1.

The first wavelength conversion pattern 240 and the second wavelength conversion pattern 250 may each include the first wavelength conversion particle WCP1 that converts the first light of blue to the fourth light of yellow. Thus, the blue first light emitted from the light emitting element LE disposed in the second emitting area EA2 and the third emitting area EA3, respectively, may be converted into yellow fourth light. In each of the first wavelength conversion pattern 240 and the second wavelength conversion pattern 250, the white fifth light is emitted by mixing the blue first light and the yellow fourth light, and the fifth light may be converted into the second light in the second color filter CF2 and converted into the third light in the third color filter CF3 and emitted.

Hereinafter, the manufacturing process of the display device 10 according to an embodiment will be described with reference to the other drawings.

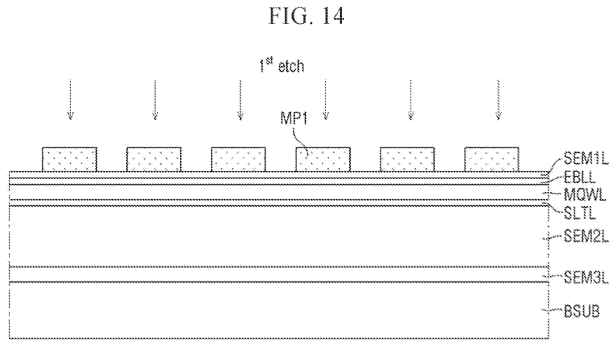

FIGS. 14 to 24 are diagrams to illustrate a manufacturing method of a display device according to embodiments of the present disclosure.

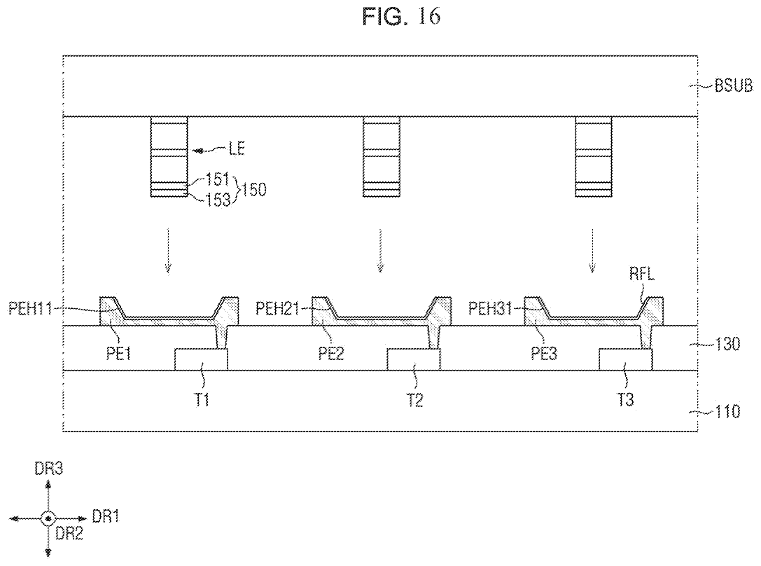

FIGS. 14 to 24 illustrate the structure of each layer of the display device 10 in the sequence of formation, in cross-sectional and plan view, respectively. FIGS. 16 to 20 focus on a process for aligning and bonding the light emitting element LE to the pixel electrode PE, each of which may correspond roughly to the cross-sectional view of FIG. 6.

Referring to FIG. 14, a plurality of semiconductor material layers SEM3L, SEM2L, SLTL, MQML, EBLL, and SEM1L are formed on a base substrate BSUB and a plurality of light emitting elements LE are formed.

First, the base substrate BSUB is prepared. In an embodiment, the base substrate BSUB may be a sapphire substrate Al₂O₃ or a silicon wafer including silicon. However, embodiments of the present disclosure are not necessarily limited thereto, and an embodiment in which the base substrate BSUB is a sapphire substrate will be described as an example.

The plurality of semiconductor material layers SEM3L, SEM2L, SLTL, MQML, EBLL, and SEM1L are formed on the base substrate BSUB. In an embodiment, the plurality of semiconductor material layers grown by the epitaxial method may be formed by growing a seed crystal. Methods for forming semiconductor material layers include electron beam deposition, physical vapor deposition (PVD), chemical vapor deposition (CVD), and plasma laser deposition (PLD), dual-type thermal evaporation, sputtering, metal organic chemical vapor deposition (MOCVD), or the like. However, embodiments of the present disclosure are not necessarily limited thereto.

A precursor material for forming the plurality of semiconductor material layers is not particularly limited within the range that may be conventionally selected for forming the subject material. In one example, the precursor material may be a metal precursor including an alkyl group such as a methyl or ethyl group. For example, the precursor material may be a compound such as trimethyl gallium (Ga(CH₃)₃), trimethyl aluminum (Al(CH₃)₃), triethyl phosphate ((C₂H₅)₃PO₄). However, embodiments of the present disclosure are not necessarily limited thereto.

In an embodiment, a third semiconductor material layer SEM3L is formed on the base substrate BSUB. While the drawings illustrate the third semiconductor material layer SEM3L being further stacked, embodiments of the present disclosure are not necessarily limited thereto, and a plurality of layers may be formed. The third semiconductor material layer SEM3L may be disposed to reduce a lattice constant difference between a second semiconductor material layer SEM2L and the base substrate BSUB. For example, the third semiconductor material layer SEM3L may include an undoped semiconductor, which may be an n-type or p-type undoped material. In an embodiment, the third semiconductor material layer SEM3L may be at least one of undoped InAlGaN, GaN, AlGaN, InGaN, AlN, and InN. However, embodiments of the present disclosure are not necessarily limited thereto.

The second semiconductor material layer SEM2L, a superlattice material layer SLTL, an active material layer MQWL, an electronic blocking material layer EBLL, and the first semiconductor material layer SEM1L are sequentially formed on the third semiconductor material layer SEM3L (e.g., in the third direction DR3) using the method described above.

In an embodiment, the plurality of semiconductor material layers SEM3L, SEM2L, SLTL, MQML, EBLL, and SEM1L are then etched to form the plurality of light emitting elements LE1.

For example, a plurality of first mask patterns MP1 are formed on the first semiconductor material layer SEM1L. The first mask pattern MP1 may be a hard mask including an inorganic material or a photoresist mask including the organic material. The first mask pattern MP1 prevents the lower plurality of semiconductor material layers SEM3L, SEM2L, SLTL, MQML, EBLL, and SEM1L from being etched. A portion of the plurality of semiconductor material layers is then etched (1^{st} etch) using the plurality of first mask patterns MP1 as a mask to form the plurality of light emitting elements LE1.

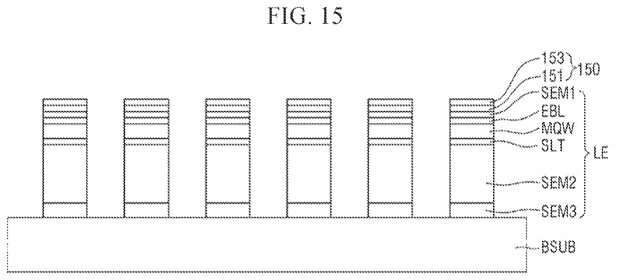

As shown in FIG. 15, on the base substrate BSUB, the plurality of semiconductor material layers SEM3L, SEM2L, SLTL, MQML, EBLL, and SEM1L that are non-overlapping with the first mask pattern MP1 are etched and removed, and the portions that are not etched overlapping with the first mask pattern MP1 may be formed into the plurality of light emitting elements LE1.

The semiconductor material layers may be etched by conventional methods. For example, in an embodiment the process of etching the semiconductor material layers may be dry etching, wet etching, reactive ion etching (RIE), deep reactive ion etching (DRIE), inductively coupled plasma reactive ion etching (ICP-RIE), or the like. In the case of dry etching methods, anisotropic etching is possible, which may be suitable for vertical etching. When utilizing the etching method described above, the etchant may be Cl₂ or O₂. However, embodiments of the present disclosure are not necessarily limited thereto.

The plurality of semiconductor material layers SEM3L, SEM2L, SLTL, MQML, EBLL, and SEM1L overlapping the first mask pattern MP1 are not etched but are formed into the plurality of light emitting elements LE. Thus, the plurality of light emitting elements LE are formed including a third semiconductor layer SEM3, the second semiconductor layer SEM2, the superlattice layer SLT, the active layer MQW, the electronic blocking layer EBL, and the first semiconductor layer SEM1. In an embodiment, the connection electrode 150 is then formed on the first semiconductor layer SEM1 of the light emitting element LE.

In an embodiment, the connection electrodes 150 are formed on the plurality of light emitting elements LE by stacking the connection electrode material layers on the base substrate BSUB and etching them. For example, the connection electrode 150 including the reflective layer 151 and the connection layer 153 may be formed by sequentially stacking a reflective layer material layer and the connection layer material layer on the base substrate BSUB and etching them in batches. The connection electrode 150 may be formed directly on the top surface of the first semiconductor layer SEM1 of the light emitting element LE. In an embodiment, the reflective layer 151 of the connection electrode 150 may directly contact the top surface of the first semiconductor layer SEM1 of the light emitting element LE. The light emitting element LE may include the connection electrode 150.

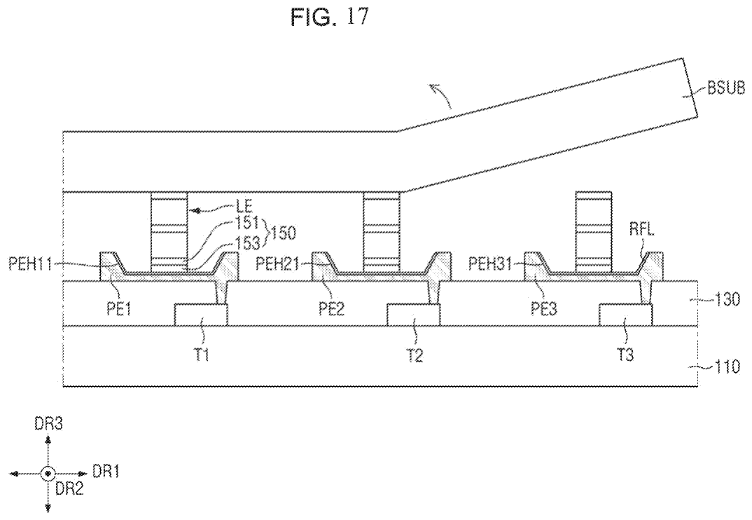

Referring to FIGS. 16 and 17, the light emitting element LE is then transferred to the first substrate 110, which includes the pixel electrode PEL including the groove PEH.

For example, the first switching element T1 is formed on the first substrate 110, and the insulating layer 130 is formed on the first switching element T1. In an embodiment, the first substrate 110 may be a transparent insulating substrate and may be a glass or quartz substrate. The first switching element T1 may include a plurality of thin film transistors and capacitors. The insulating layer 130 may be formed with a contact hole exposing the first switching element T1.

In an embodiment, the pixel electrodes PE1, PE2, and PE3 are then formed by laminating a metal material on the insulating layer 130. The pixel electrodes PE1, PE2, and PE3 may be connected to the first switching element T1 through contact holes formed in the insulating layer 130.

In an embodiment, the pixel electrodes PE1, PE2, and PE3 are then patterned to form grooves, such as the first to third grooves PEH1, PEH2, and PEH3 in the first to third pixel electrodes PE1, PE2, and PE3. The reflective material is coated in the formed first to third grooves PE1, PE2, and PE3 to form the reflective layer RFL. The reflective material may be a material having a reflectivity of at least 80%. For example, in an embodiment the reflective material may be Ag, Ni, Cr, or the like.

The base substrate BSUB is then disposed on the first substrate 110, and the light emitting elements LE formed on the base substrate BSUB are aligned to be disposed within the first to third grooves PEH1, PEH2, and PEH3 of the first to third pixel electrodes PE1, PE2, and PE3. At this time, the connection electrodes 150 of the light emitting elements LE formed on the base substrate BSUB are aligned to face the first substrate 110.

The first substrate 110 and the base substrate BSUB are then bonded together. For example, the connection electrode 150 of the light emitting element LE formed on the base substrate BSUB is contacted with the reflective layer RF. The first substrate 110 and the base substrate BSUB are then bonded by melting the connection layer 153 of the light emitting element LE and the reflective layer RF. At this time, the plurality of light emitting elements LE are bonded in the first to third grooves PEH1, PEH2, and PEH3 of the first to third pixel electrodes PE1, PE2, and PE3. At this time, the light emitting elements LE are bonded to the upper surface of the reflective layer RF. As for the melt bonding, in an embodiment a laser may be irradiated onto the reflective layer RF from the top of the base substrate BSUB. The laser-irradiated reflective layer RFL may conduct high heat from the laser and bond the interface with the connection layer 153 of the light emitting element LE. The source of the laser used for the melting bonding may be a YAG. However, embodiments of the present disclosure are not necessarily limited thereto.

In an embodiment, the base substrate BSUB may then be separated from the plurality of light emitting elements LE.

In an embodiment, the base substrate BSUB may then be separated from the third semiconductor layer SEM3 of the light emitting element LE. In an embodiment, the process for separating the base substrate BSUB may be a laser lift off (LLO) process. The laser lift off process utilizes a laser, and a KrF excimer laser (248 nm wavelength) may be used as the source. In an embodiment, the energy density of the excimer laser is irradiated in the range of about 550 mJ/cm² to 950 mJ/cm², and the incident area may be in the range of 50×50 μm² to 1×1 μm². However, embodiments of the present disclosure are not necessarily limited thereto. The base substrate BSUB may be separated from the light emitting element LE by irradiating the base substrate BSUB with the laser. The third semiconductor layer SEM3 may then be removed by gluing or the like.

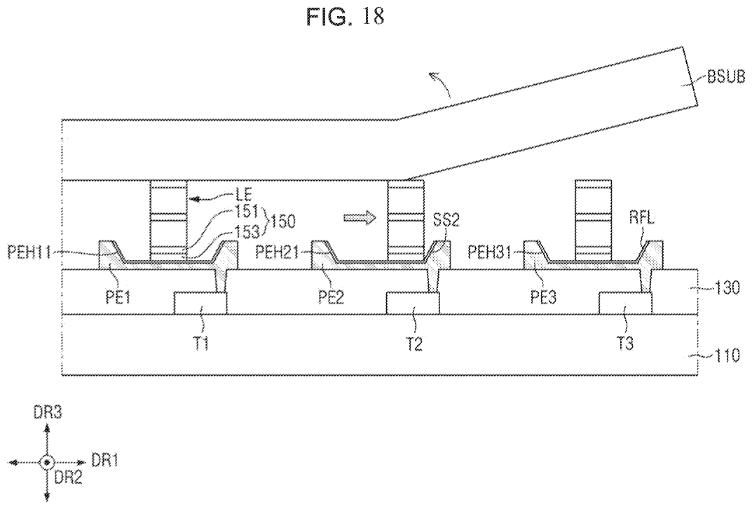

On the other hand, referring to FIG. 18, when the base substrate BSUB is separated from the plurality of light emitting elements LE, the light emitting elements LE may deviate from an aligned position. Even in this case, the light emitting elements LE are disposed in the first to third grooves PEH1, PEH2, and PEH3 of the first to third pixel electrodes PE1, PE2, and PE3, so that the light emitting element LE is not moved out of (e.g., protrudes to be in a non-overlapping relationship with) the first to third pixel electrodes PE1, PE2, and PE3 by the inclined surface SS1 of the first to third grooves PEH1, PEH2, and PEH3 of the first to third pixel electrodes PE1, PE2, and PE3.

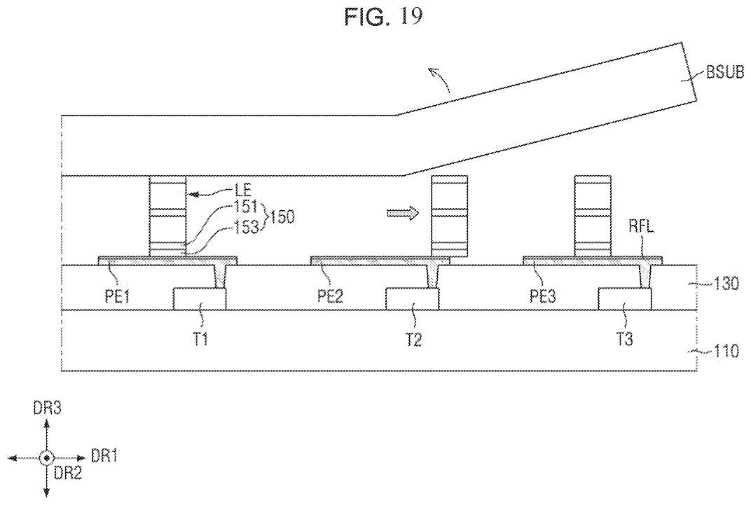

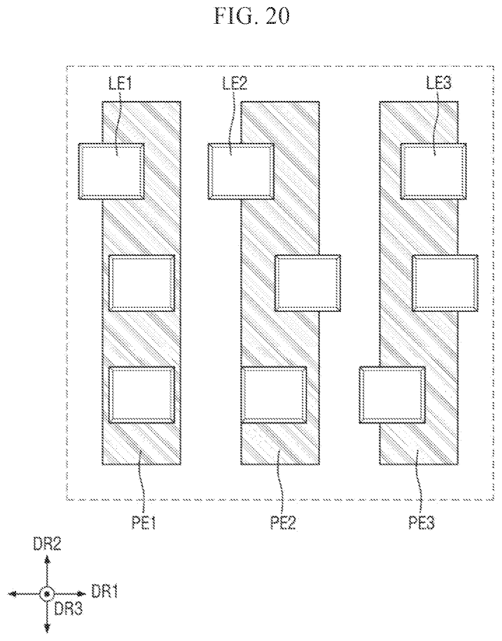

On the other hand, referring to FIGS. 19 and 20, in a comparative embodiment in which the first to third pixel electrodes PE1, PE2, and PE3 do not include the first to third grooves PEH1, PEH2, and PEH3, the light emitting elements LE may be moved to the sides of the first to third pixel electrodes PE1, PE2, and PE3 so that they at least partially do not overlap the first to third pixel electrodes PE1, PE2, and PE3.

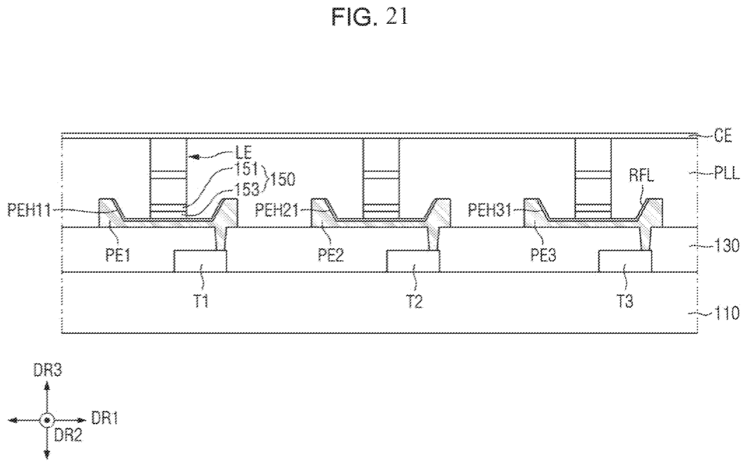

Referring to FIG. 21, the planarization layer PLL is then formed on the insulating layer 130 and each of the first and second pixel electrodes PEL and PE2, and the common electrode CE is formed on the planarization layer PLL.

For example, the organic material is applied to the first substrate 110 to form the planarization layer PLL. The planarization layer PLL is formed with a thickness lower than the height of the light emitting element LE so that the second semiconductor layer SEM2 and the third semiconductor layer SEM3 of the light emitting element LE are exposed.

A transparent conductive material is then deposited on the planarization layer PLL to form the common electrode CE. The common electrode CE is formed to cover the light emitting element LE and the planarization layer PLL. The common electrode CE directly contacts the second semiconductor layer SEM2 of the light emitting element LE exposed above the planarization layer PLL.

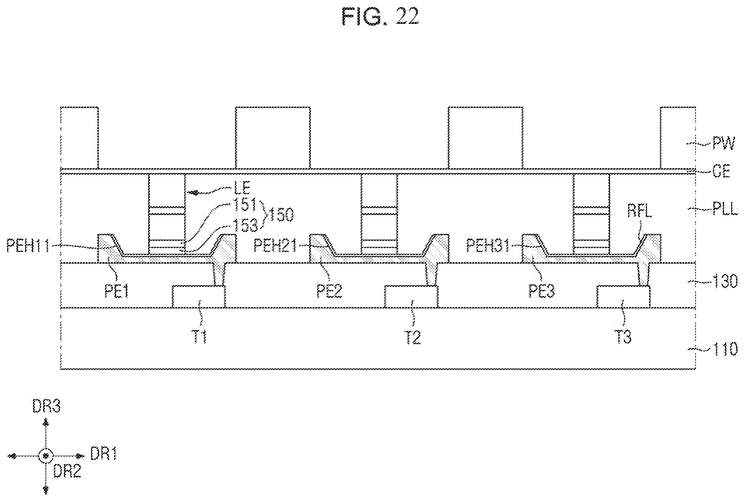

Referring to FIG. 22, the organic material is then applied to the first substrate 110 including the common electrode CE and patterned to form the partition wall PW. The plurality of openings, for example, the first opening OP1 is formed to correspond to the first light emitting area EA1, and the second opening OP2 is formed to correspond to the second light emitting area EA2. In an embodiment, other openings may also be formed to correspond to other light emitting areas.

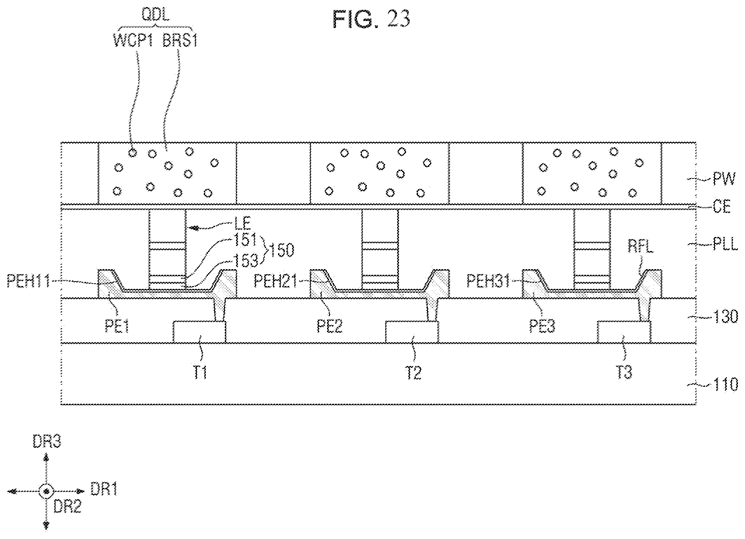

Referring to FIG. 23, the wavelength conversion layer QDL may then be formed to fill the plurality of openings OP1. In an embodiment, the wavelength conversion layer QDL may be formed by a solution process such as inkjet printing, imprinting, or the like of a solution of the first wavelength conversion particle WCP1 mixed with the first base resin BRS1. However, embodiments of the present disclosure are not necessarily limited thereto. Each of the wavelength conversion layers QDL may be formed in the plurality of openings OP1 and may be formed to overlap with the plurality of emitting areas EA1.

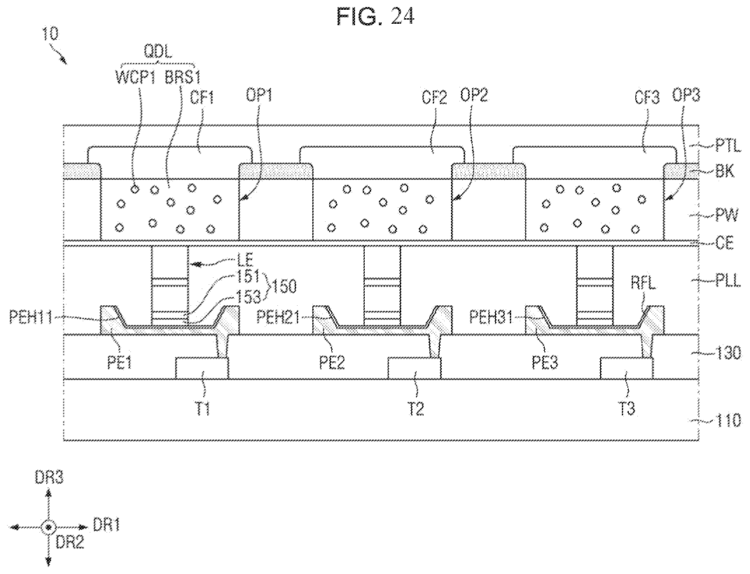

Referring to FIG. 24, the light blocking member BK is then formed on the partition wall PW. In an embodiment, the light blocking member BK is formed by applying a blocking material and patterning it. The light blocking member BK is formed to overlap the non-emitting area NEA and non-overlap the first and second emitting areas EA1 and EA2.

The color filter CF1 is then formed on the wavelength conversion layer QDL compartmentalized by the light blocking member BK. The color filter CF1 may be formed by a photo process. In an embodiment, the thickness of the color filter CF1 may be formed to be about 1 μm or less. However, embodiments of the present disclosure are not necessarily limited thereto.

In an embodiment, the first color filter material layer is applied on the partition wall PW and the wavelength conversion layer QDL and patterned by the photo process to form the first color filter CF1 overlapping the first opening OP1. Similarly, the other color filters are formed to overlap the respective openings through the patterning process.

The display device 10 according to an embodiment is then manufactured by forming the protective layer PTL on the light blocking member BK and the color filter CF1.

As described with reference to FIGS. 14 to 24, the display device 10 according to an embodiment may prevent misalignment of the light emitting elements LE on the pixel electrodes PE1, PE2, and PE3 having the groove PEH, thereby preventing defects. Accordingly, the light emitting element LE may be prevented from protruding outwardly from the pixel electrodes PE1, PE2, and PE3 in a plane.

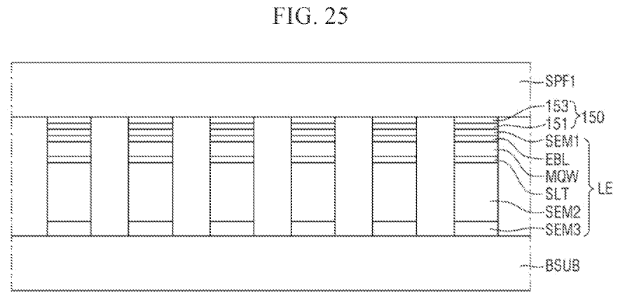

FIGS. 25 to 31 are cross-sectional views illustrating a manufacturing process of a display device according to an embodiment.

Referring to FIGS. 25 to 31, an embodiment differs from an embodiment in the above-described FIGS. 14 to 24 based on the attaching, stretching, and detaching a plurality of films on the plurality of light emitting elements LE formed on the base substrate BSUB to bond the light emitting elements LE to the display substrate 100. A process that differs from the above-described embodiment will be described, and similar or identical elements previously described with respect to FIGS. 14 to 24 may be omitted for economy of description.

Referring to FIG. 25, a first support film SPF1 is attached to the plurality of light emitting elements LE of the base substrate BSUB manufactured in FIG. 15.

For example, the first support film SPF1 is attached to the plurality of light emitting elements LE. The first support film SPF1 may be aligned on the plurality of light emitting elements LE and attached to each of the connection electrodes 150 of the plurality of light emitting elements LE. The plurality of light emitting elements LE may be arranged in a large number so that they may be attached to the first support film SPF1 without being detached.

The first support film SPF1 may comprise a support layer and an adhesive layer disposed on the support layer. In an embodiment, the support layer may be made of a transparent, mechanically stable material that allows light to pass through. For example, the support layer may include a transparent polymer such as polyester, polyacrylic, polyepoxy, polyethylene, polystyrene, polyethylene terephthalate, or the like. However, embodiments of the present disclosure are not necessarily limited thereto. The adhesive layer may include an adhesive material for bonding the light emitting element LE. For example, in an embodiment the adhesive material may include urethane acrylate, epoxy acrylate, polyester acrylate, or the like. However, embodiments of the present disclosure are not necessarily limited thereto. The adhesive material may be a material whose adhesion changes as ultraviolet UV light or heat is applied, such that the adhesive layer may be easily separated from the light emitting element LE.

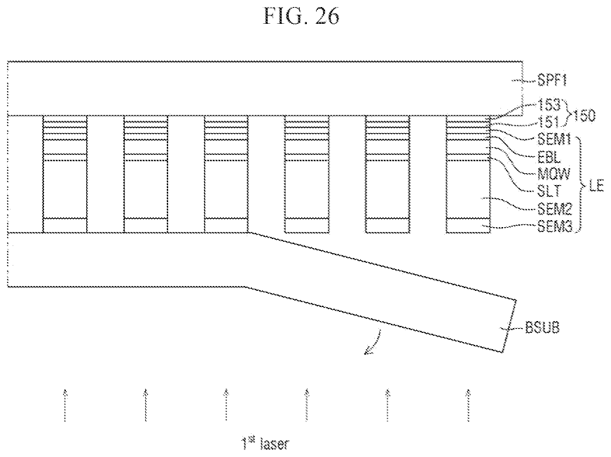

Referring to FIG. 26, the base substrate BSUB is then irradiated with the first laser to separate the base substrate BSUB. The base substrate BSUB is separated from each third semiconductor layer SEM3 of the plurality of light emitting elements LE. Since the separation process of the base substrate BSUB has been described above, the description will be omitted for economy of description.

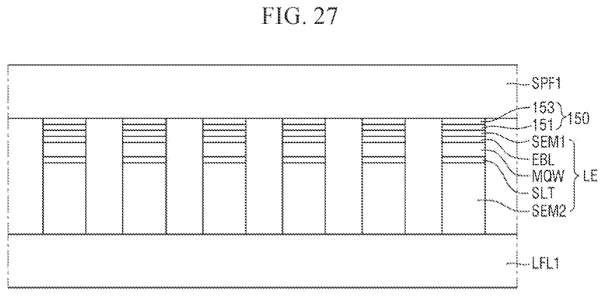

Referring to FIG. 27, a first transfer film LFL1 is attached to the plurality of light emitting elements LE from which the base substrate BSUB is separated.

For example, the first transfer film LFL1 is attached to each third semiconductor layer SEM3 of the plurality of light emitting elements LE. The first transfer film LFL1 may be aligned on the plurality of light emitting elements LE and attached to each third semiconductor layer SEM3 of the plurality of light emitting elements LE.

The first transfer film LFL1 may include a stretchable material. For example, in an embodiment the stretchable material may include polyolefine, polyvinyl chloride (PVC), elastomeric silicone, elastomeric polyurethane, elastomeric polyisoprene, or the like. However, embodiments of the present disclosure are not necessarily limited thereto. The first transfer film LFL1 may also include the support layer and the adhesive layer, such as the first support film SPF1 described above, to bond and support the plurality of light emitting elements LE. The first transfer film LFL1 may also include the support layer and the adhesive layer, such as the first support film SPF1 described above, to bond and support the plurality of light emitting elements LE.

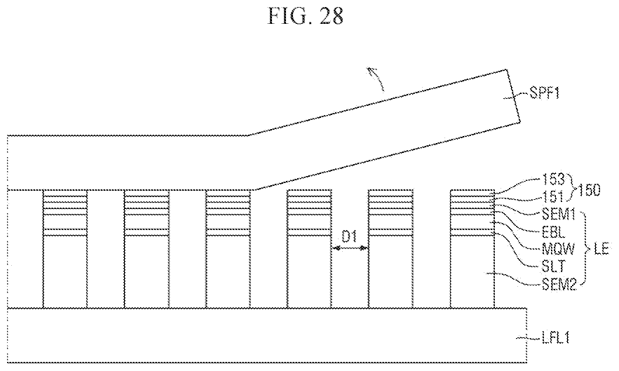

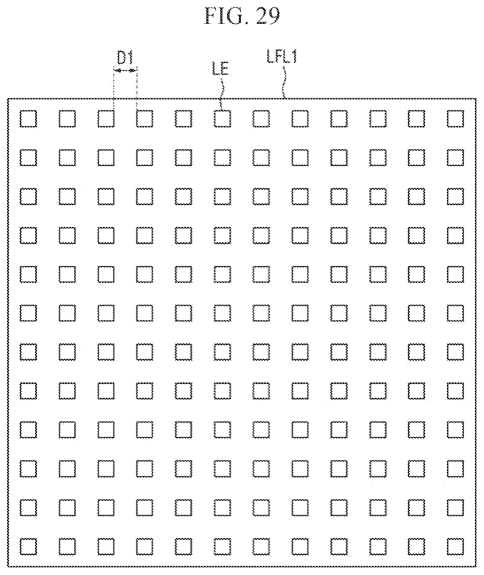

Referring to FIGS. 28 and 29, the first support film SPF1 is then separated from the plurality of light emitting elements LE. The first support film SPF1 may be physically or naturally separated after applying ultraviolet light or heat to the first support film SPF1 to reduce the adhesion of the adhesive layer of the first support film SPF1. The plurality of light emitting elements LE may be disposed in a dot shape on the first transfer film LFL1, spaced apart by a predetermined first distance D1.

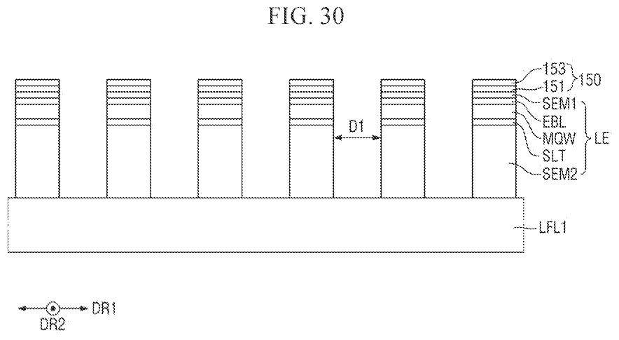

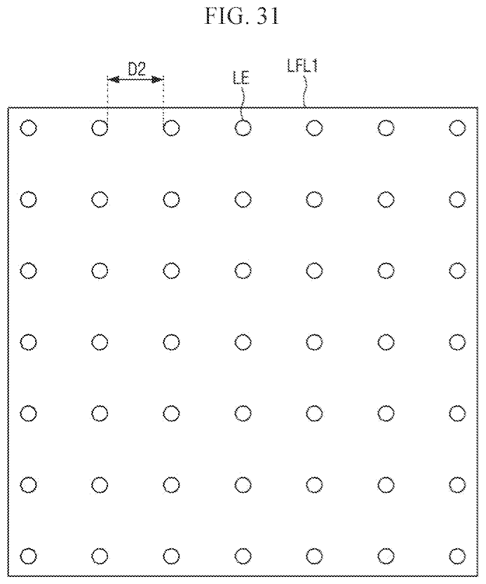

Referring to FIGS. 30 and 31, the first transfer film LFL1 is then stretched. The first transfer film LFL1 may be stretched in two dimensions, including the first direction DR1 and the second direction DR2. As the first transfer film LFL1 is stretched, the plurality of light emitting elements LE bonded on the first transfer film LFL1 may be spaced apart by a second distance D2. The plurality of light emitting elements LE may be uniformly spaced apart in the second distance D2 that is larger than the first distance D1 described above.

The stretching strength (e.g., tensile strength) of the first transfer film LFL1 may be adjusted according to the desired second distance D2 of the light emitting elements LE, for example, about 120 gf/inch. However, embodiments of the present disclosure are not necessarily limited thereto and may be adjusted according to the second distance D2.

The plurality of light emitting elements LE may then be bonded to the first substrate 110 by bonding the first transfer film LFL1 to the first substrate 11, and the display device 10 may be manufactured through a process such as that described in FIGS. 16 to 24.

In this embodiment, the density of the light emitting elements LE may be adjusted to correspond to the pixel size by manufacturing the display device 10 using the transfer film. Accordingly, the display device may be relatively easily formed by arranging the light emitting elements LE to correspond to pixels of various sizes.

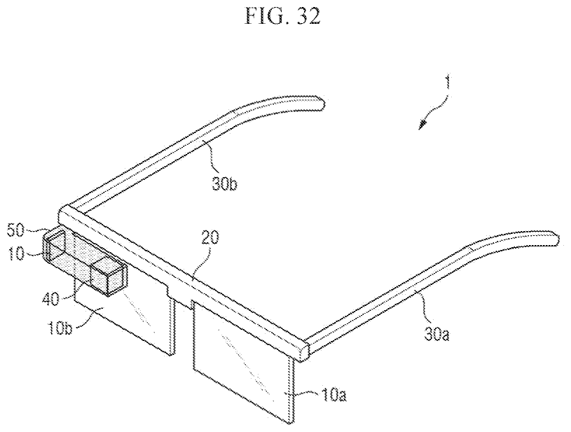

FIG. 32 is a diagram illustrating a virtual reality device including a display device according to an embodiment. FIG. 32 illustrates a virtual reality device 1 in which the display device 10 according to an embodiment is used.

Referring to FIG. 32, the virtual reality device 1 according to an embodiment may be a device in a form of glasses. The virtual reality device 1 according to an embodiment may include a display device 10, a left-eye lens 10a, a right-eye lens 10b, a support frame 20, left and right legs 30a and 30b, a reflective member 40, and a display device housing 50.

FIG. 32 illustrates the virtual reality device 1 including the two legs 30a and 30b. However, embodiments of the present disclosure are not necessarily limited thereto. The virtual reality device 1 according to an embodiment may be used in a head-mounted display including a head-mounted band that may be mounted on a head instead of the legs 30a and 30b. For example, the virtual reality device 1 according to an embodiment may not be limited to the example shown in FIG. 32, and may be applied in various forms and in various electronic devices.

The display device housing 50 may receive the display device 10 and the reflective member 40. An image displayed on the display device 10 may be reflected from the reflective member 40 and provided to a user's right eye through the right-eye lens 10b. The user may then view a virtual reality image displayed on the display device 10 via the right eye.

FIG. 32 illustrates that the display device housing 50 is disposed at a right end of the support frame 20. However, embodiments of the present disclosure are not necessarily limited thereto. For example, the display device housing 50 may be disposed at a left end of the support frame 20. In this embodiment, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be disposed at each of the left end and the right end of the support frame 20. In this embodiment, the user may view the virtual reality image displayed on the display device 10 via both the left eye and the right eye.

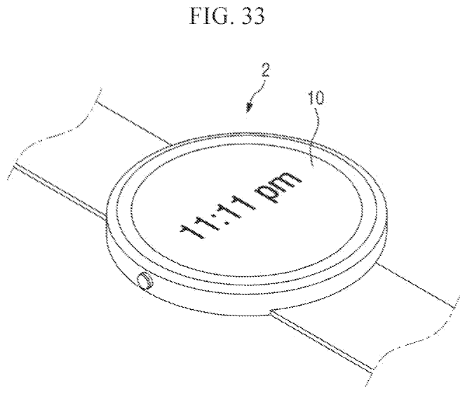

FIG. 33 is a diagram illustrating a smart device including a display device according to an embodiment.

Referring to FIG. 33, a display device 10 according to an embodiment may be applied to a smart watch 2 as one of smart devices.

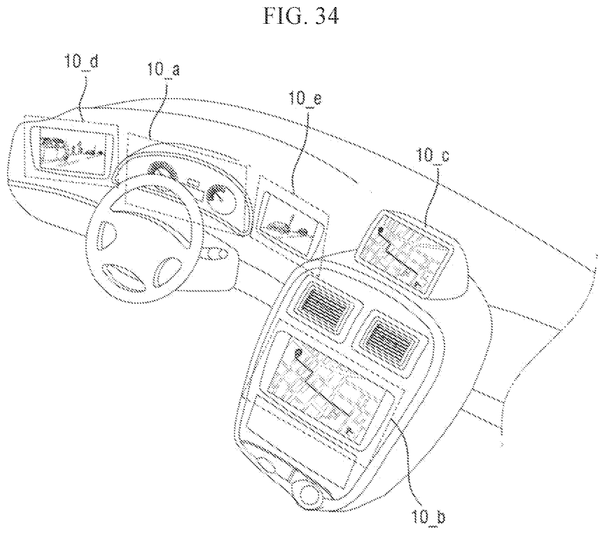

FIG. 34 is a diagram illustrating a vehicle including a display device according to an embodiment. FIG. 34 illustrates a vehicle in which display devices according to an embodiment are used.

Referring to FIG. 34, the display devices 10_a, 10_b, and 10_c according to an embodiment may be applied to the dashboard of the vehicle, applied to the center fascia of the vehicle, or applied to a CID (Center Information Display) disposed on the dashboard of the vehicle. Further, each of the display devices 10_d and 10_e according to an embodiment may be applied to each room mirror display that replaces each of side-view mirrors of the vehicle.

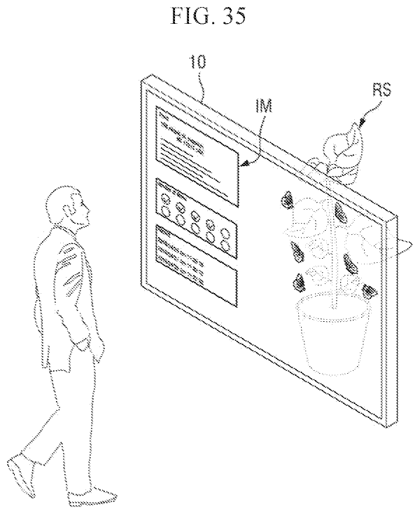

FIG. 35 is an example diagram illustrating a transparent display device including a display device according to an embodiment.

Referring to FIG. 35, a display device according to an embodiment may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In an embodiment in which the display device 10 is applied to the transparent display device, the first substrate 110 of the display device 10 shown in FIG. 6 may include a light transmitting portion that may transmit light therethrough or may be made of a material that may transmit light therethrough.

In concluding the detailed description, those skilled in the art will appreciate that many variations and modifications can be made to the described embodiments without substantially departing from the principles of the present disclosure. Therefore, the described embodiments of the present disclosure are used in a generic and descriptive sense only and not for purposes of limitation.

What is claimed is:

1. A display device comprising:
a substrate;
a pixel electrode disposed on the substrate, the pixel electrode having one or more grooves defined therein; and
light emitting elements respectively disposed in the one or more grooves.

2. The display device of claim 1, further comprising:
a planarization layer disposed between the light emitting elements; and
a common electrode disposed on the planarization layer and the light emitting elements.

3. The display device of claim 1, wherein a depth of the one or more grooves is in a range of about 10% to about 90% of a thickness of the pixel electrode.

4. The display device of claim 3, wherein:
each of the light emitting elements disposed in the one or more grooves includes an active layer; and
the depth of each of the one or more grooves is greater than a height of the active layer.

5. The display device of claim 3, wherein each of the light emitting elements disposed in the one or more grooves includes an active layer disposed within the one or more grooves.

6. The display device of claim 3, wherein:
each of the one or more grooves has a bottom surface and an inclined surface extending from the bottom surface; and
an inclined angle formed between the inclined surface of the one or more grooves and the bottom surface of the one or more grooves is in a range of about 90 degrees to about 160 degrees.

7. The display device of claim 6, wherein a reflective layer is disposed on the inclined surface of the one or more grooves and the bottom surface of the one or more grooves, the reflective layer has a higher reflectivity than a reflectivity of the pixel electrode.

8. The display device of claim 7, wherein the reflective layer has a reflectivity greater than or equal to about 80%.

9. The display device of claim 6, wherein an area of the bottom surface of each of the one or more grooves is in a range of about 110% to about 200% of an area of the light emitting elements disposed within each of the one or more grooves.

10. The display device of claim 2, further comprising:
a wavelength conversion part disposed on the common electrode, wherein the wavelength conversion part includes partition walls separating light emitting areas from non-emitting areas;
a wavelength conversion layer disposed between the partition walls and overlapping the light emitting areas;
a light blocking member disposed on the partition walls; and
color filters disposed on the wavelength conversion layer.

11. A display device comprising:
a substrate;
pixel electrodes disposed on the substrate, each of the pixel electrodes having one or more grooves defined therein, the one or more grooves are spaced apart from each other;
light emitting elements respectively disposed within the one or more grooves,
wherein the light emitting elements disposed on different pixel electrodes of the pixel electrodes emit light have different wavelengths from each other,
wherein a center of the one or more grooves is disposed on a respective central axis of the pixel electrodes.

12. The display device of claim 11, wherein the light emitting elements include:
a first light emitting element having a center wavelength band in a range of 420 nm to 480 nm;
a second light emitting element having a center wavelength band in a range of 500 nm to 580 nm; and
a third light emitting element having a center wavelength band in a range of 600 nm to 680 nm.

13. The display device of claim 11, further comprising:
a planarization layer disposed between the light emitting elements; and
a common electrode disposed on the planarization layer and the light emitting elements.

14. The display device of claim 11, wherein a depth of each of the one or more grooves is in a range of about 10% to about 90% of a thickness of each of the pixel electrodes.

15. The display device of claim 13, wherein:
each of the light emitting elements disposed in the one or more grooves includes an active layer; and
a depth of each of the one or more grooves is greater than a height of the active layer.

16. The display device of claim 13, wherein:
each of the one or more grooves has a bottom surface and an inclined surface extending from the bottom surface; and
an inclined angle formed between the inclined surface of each of the one or more grooves and the bottom surface of each of the one or more grooves is in a range of about 90 degrees to about 160 degrees.

17. The display device of claim 16, wherein a reflective layer is disposed on the inclined surface of the one or more grooves and the bottom surface of the one or more grooves, the reflective layer has a higher reflectivity than a reflectivity of the pixel electrodes.

18. The display device of claim 17, wherein the reflective layer has a reflectivity greater than or equal to about 80%.

19. The display device of claim 16, wherein an area of the bottom surface of each of the one or more grooves is in a range of about 110% to about 200% of an area of each of the light emitting elements disposed within the one or more grooves.

20. The display device of claim 13, further comprising:
a wavelength conversion part disposed on the common electrode,
wherein the wavelength conversion part includes partition walls separating light emitting areas from non-emitting areas;
a wavelength conversion layer disposed between the partition walls and overlapping the light emitting areas;
a light blocking member disposed on the partition walls; and
color filters disposed on the wavelength conversion layer.
